(19) United States
(12) Patent Application Publication
(10) Pub. No.: US 2008/0061678 A1
(43) Pub. Date: Mar. 13, 2008

(54) LIGHT EMITTING DEVICE

(75) Inventors: Takafumi HAMANO, Fukuoka (JP); Kazuo NISHIMURA, Osaka (JP); Keniti MASUMOTO, Osaka (JP)

Correspondence Address: GREENBLUM & BERNSTEIN, P.L.C., 1950 ROLAND CLARKE PLACE, RESTON, VA, 20191, US

(73) Assignee: MATSUSHITA ELECTRIC INDUSTRIAL CO., LTD., Osaka (JP)

(21) Appl. No.: 11/853,222

(22) Filed: Sep. 11, 2007

(30) Foreign Application Priority Data
Sep. 12, 2006 (JP) 2006-247265
Dec. 18, 2006 (JP) 2006-340372

(51) Int. Cl. H01J 1/62

(52) U.S. Cl. 313/498

(57) ABSTRACT

A light emitting device includes an electroluminescent element 110 and a light detection element 120 that detects light output from the electroluminescent element 110, the electroluminescent element 110 and the light detection element 120 being disposed to be laminated. The light detection element 120 is formed using a thin film transistor, and the thin film transistor has a control gate 126 that is formed so as to be electrically insulated and separated from an electrode (anode 111) of the electroluminescent element 110.

### BACKGROUND

1. Field of the Invention

The present invention relates to a light emitting device used for an optical head for image formation or a display device, such as a display.

2. Describe of the Related Art

In recent years, information processing apparatuses, such as facsimiles and printers, are rapidly becoming smaller in size and cheaper. For this reason, a study to make components included in the apparatuses smaller and cheaper is proceeding.

An image forming apparatus using light forms an image by forming an electrostatic image by illuminating light on an electrically charged photoconductor so as to change an electrically charged state of the photoconductor and then transferring toner, which is adhered onto the photoconductor by static electricity, onto an object to be printed, such as a recording medium. Light illuminated onto the photoconductor is controlled by an exposure apparatus called an optical head. The optical head includes a light source, a circuit that performs a driving control of the light source, and the like. As the light source, a laser device, a light emitting diode, or an electroluminescent element is mainly used.

The basic configuration of an electroluminescent element is that a light emitting layer made of an organic material or an inorganic material is interposed between an anode and a cathode. In this case, it is possible to suppress an increase in manufacturing cost compared with a case in which a laser device or a light emitting diode is made small.

Examples in which an organic electroluminescent element using a light emitting layer made of an organic material is used as a light source of an optical head are disclosed in Patent Documents 1 and 2. In Patent Documents 1 and 2, a light detection element having a light receiving region smaller than a luminous region of a light emitting layer of an electroluminescent element is provided below the electroluminescent element so that light output from a bottom surface of a sub is not blocked. In addition, Patent Document 3 will be referred in a thirteenth embodiment.

Patent Document 1: JP-A-2002-144634

Patent Document 2: JP-A-2002-178560

Patent Document 3: JP-A-2000-357815

FIG. 34 is a view schematically illustrating the configuration of each of the optical heads disclosed in Patent Documents 1 and 2. As shown in FIG. 34, the optical head is a laminate body including layers formed of several kinds of materials. In the optical head, a base coat layer 101 is provided on a glass substrate 100, and a driving circuit, an electroluminescent element serving as a light source, and a circuit for driving the electroluminescent element are formed. In addition, a light detection element 120 is provided on a part of the base coat layer 101.

As shown in FIGS. 35A and 35B that are enlarged views of main parts, the light detection element 120 is formed by laminating the light detection element 120 and a light emitting element 110 on the transmissive substrate 100 (refer to FIG. 34) and extracts light from the transmissive substrate 100 side.

The light detection element 120 is configured to include: source and drain regions 121S and 121D that are n-type impurity regions formed by injecting impurity ions into an island region 121 made of a polycrystalline silicon; and a channel region 121i that is a non-doped i layer positioned between the source and drain regions 121S and 121D. FIG. 35B is a cross-sectional view taken along the line XXXVB-XXXVB of FIG. 35A. In addition, source and drain electrodes 125S and 125D made of polycrystalline silicon are formed in the vicinity of the source and drain regions 121S and 121D, respectively.

According to the configuration, the i layer that forms the channel region 121i of a thin film transistor serving as the light detection element 120 is opposite to an anode 111 of the light emitting element 110 with an insulating layer interposed therebetween.

For this reason, the channel region 121i of the thin film transistor has an electric potential depending on the electric potential of the anode 111, a change in electric potential of the anode 111 causes a variation in a depletion layer formed in the channel layer 121i or a variation in transport characteristics of charges in the source and drain regions 121S and 121D. As a result, since charge generation and transport characteristics of the light detection element 120 formed of a thin film transistor is affected, a detected current may be fluctuated.

### SUMMARY

The invention has been finalized in view of the above, it is an object of the invention to provide a light emitting device capable of detecting the amount of light with high accuracy by improving the detection accuracy of a light amount sensor (light detection element) and capable of emitting a desired amount of light.

According to an aspect of the invention, there is provided a light emitting device including an electroluminescent element and a light detection element that detects light output from the electroluminescent element, the electroluminescent element and the light detection element being disposed to be laminated. The light detection element is formed using a thin film transistor, and the thin film transistor has a control gate that is formed so as to be electrically insulated and separated from an electrode of the electroluminescent element.

According to the configuration of the light emitting device of the invention, since a gate exists on at least a channel layer of a light detection element, the electric potential of a sensor is uniquely determined by the electric potential of the gate independently from the electric potential of an anode of a light emitting element and the characteristics of the sensor can be stabilized. Therefore, since the electric potential of a channel region of a thin film transistor can be controlled by the electric potential of the control gate without being affected by the electric potential of an electrode of the electroluminescent element, it is possible to reduce a deviation in detection accuracy and to realize highly precise light amount detection.

### BRIEF DESCRIPTION OF THE DRAWINGS

FIG. 1A is an explanatory view schematically illustrating a light emitting device according to a first embodiment of the invention.

FIG. 1B is an explanatory view schematically illustrating the light emitting device according to the first embodiment of the invention.

FIG. 2A is an explanatory view schematically illustrating a light emitting device according to a second embodiment of the invention.

FIG. 2B is an explanatory view schematically illustrating the light emitting device according to the second embodiment of the invention.

FIG. 3A is an explanatory view schematically illustrating a light emitting device according to a third embodiment of the invention.

FIG. 3B is an explanatory view schematically illustrating the light emitting device according to the third embodiment of the invention.

FIG. 4A is an explanatory view schematically illustrating a light emitting device according to a fourth embodiment of the invention.

FIG. 4B is an explanatory view schematically illustrating the light emitting device according to the fourth embodiment of the invention.

FIG. 5A is an explanatory view schematically illustrating a light emitting device according to a fifth embodiment of the invention.

FIG. 5B is an explanatory view schematically illustrating the light emitting device according to the fifth embodiment of the invention.

FIG. 6A is an explanatory view schematically illustrating a light emitting device according to a sixth embodiment of the invention.

FIG. 6B is an explanatory view schematically illustrating the light emitting device according to the sixth embodiment of the invention.

FIG. 7A is an explanatory view schematically illustrating a light emitting device according to a seventh embodiment of the invention.

FIG. 7B is an explanatory view schematically illustrating the light emitting device according to the seventh embodiment of the invention.

FIG. 8A is an explanatory view schematically illustrating a light emitting device according to an eighth embodiment of the invention.

FIG. 8B is an explanatory view schematically illustrating the light emitting device according to the eighth embodiment of the invention.

FIG. 9A is an explanatory view schematically illustrating a light emitting device according to a ninth embodiment of the invention.

FIG. 9B is an explanatory view schematically illustrating the light emitting device according to the ninth embodiment of the invention.

FIG. 10A is an explanatory view schematically illustrating a light emitting device according to a tenth embodiment of the invention.

FIG. 10B is an explanatory view schematically illustrating the light emitting device according to the tenth embodiment of the invention.

FIG. 11A is an explanatory view schematically illustrating a light emitting device according to an eleventh embodiment of the invention.

FIG. 11B is an explanatory view schematically illustrating the light emitting device according to the eleventh embodiment of the invention.

FIG. 12A is an explanatory view schematically illustrating a light emitting device according to a twelfth embodiment of the invention.

FIG. 12B is an explanatory view schematically illustrating the light emitting device according to the twelfth embodiment of the invention.

FIG. 13 is a cross-sectional view illustrating an optical head using a light emitting device in a first example of the invention.

FIG. 14 is a top view illustrating the configuration in the vicinity of a light detection element of the optical head in the first example of the invention.

FIG. 15 is an equivalent circuit view illustrating a light amount detection circuit of the optical head in the first example of the invention.

FIG. 16 is a cross-sectional view illustrating an optical head using a light emitting device in a second example of the invention.

FIG. 17 is a cross-sectional view illustrating an optical head using a light emitting device in a third example of the invention.

FIG. 18 is a cross-sectional view illustrating an optical head using a light emitting device in a fourth example of the invention.

FIG. 19 is a cross-sectional view illustrating an optical head using a light emitting device in a fifth example of the invention.

FIG. 20A is an explanatory view schematically illustrating a light emitting device according to a thirteenth embodiment of the invention.

FIG. 20B is an explanatory view schematically illustrating the light emitting device according to the thirteenth embodiment of the invention.

FIG. 21A is a view illustrating a simulation model in a method of manufacturing the light emitting device according to the thirteenth embodiment of the invention.

FIG. 21B is a view illustrating the simulation model in the method of manufacturing the light emitting device according to the thirteenth embodiment of the invention.

FIG. 22 is an explanatory view illustrating a simulation result in the light emitting device according to the thirteenth embodiment of the invention.

FIG. 23A is an explanatory view illustrating a simulation result in the light emitting device according to the thirteenth embodiment of the invention.

FIG. 23B is an explanatory view illustrating a simulation result in the light emitting device according to the thirteenth embodiment of the invention.

FIG. 24A is an explanatory view illustrating a simulation result in the light emitting device according to the thirteenth embodiment of the invention.

FIG. 24B is an explanatory view illustrating a simulation result in the light emitting device according to the thirteenth embodiment of the invention.

FIG. 24C is an explanatory view illustrating a simulation result in the light emitting device according to the thirteenth embodiment of the invention.

FIG. 25A is an explanatory view illustrating a simulation result in the light emitting device according to the thirteenth embodiment of the invention.

FIG. 25B is an explanatory view illustrating a simulation result in the light emitting device according to the thirteenth embodiment of the invention.

FIG. 25C is an explanatory view illustrating a simulation result in the light emitting device according to the thirteenth embodiment of the invention.

FIG. 26 is a flow chart illustrating a method of manufacturing the light emitting device according to the thirteenth embodiment of the invention.

FIG. 27 is a cross-sectional view illustrating an optical head using a light emitting device in a sixth example of the invention.

FIG. 28 is a plan view illustrating the optical head using the light emitting device in the sixth example of the invention.

FIG. 29 is a cross-sectional view illustrating an optical head using a light emitting device in a seventh example of the invention.

FIG. 30 is a cross-sectional view illustrating an optical head using a light emitting device in an eighth example of the invention.

FIG. 31 is a plan view illustrating an optical head using a light emitting device in a ninth example of the invention.

FIG. 32 is a plan view illustrating an optical head using a light emitting device in a tenth example of the invention.

FIG. 33 is a plan view illustrating an optical head using a light emitting device in an eleventh example of the invention.

FIG. 34 is a view schematically illustrating the configuration of an optical head in the related art.

FIG. 35A is a cross-sectional view illustrating a light emitting device in the related art.

FIG. 35B is a cross-sectional view illustrating the light emitting device in the related art.

### DETAILED DESCRIPTION

Hereinafter, embodiments of the invention will be described with reference to the accompanying drawings.

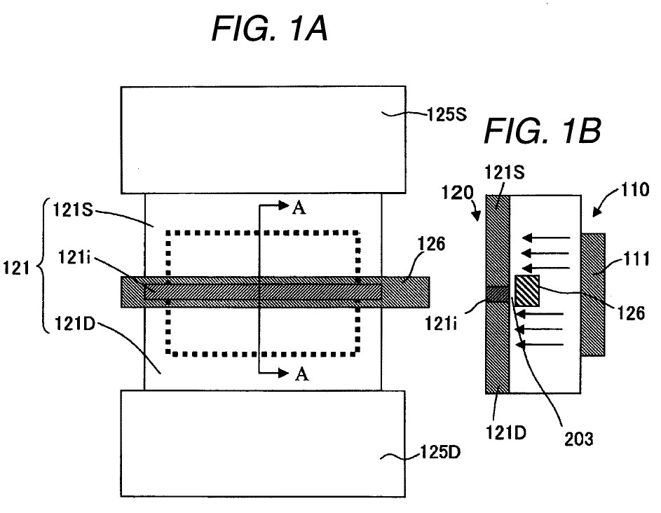

First, a conceptual explanation on embodiments of the invention will be made before proceeding to detailed explanation. FIGS. 1 to 3 are views illustrating a bottom emission and top gate type light emitting device.

### First Embodiment

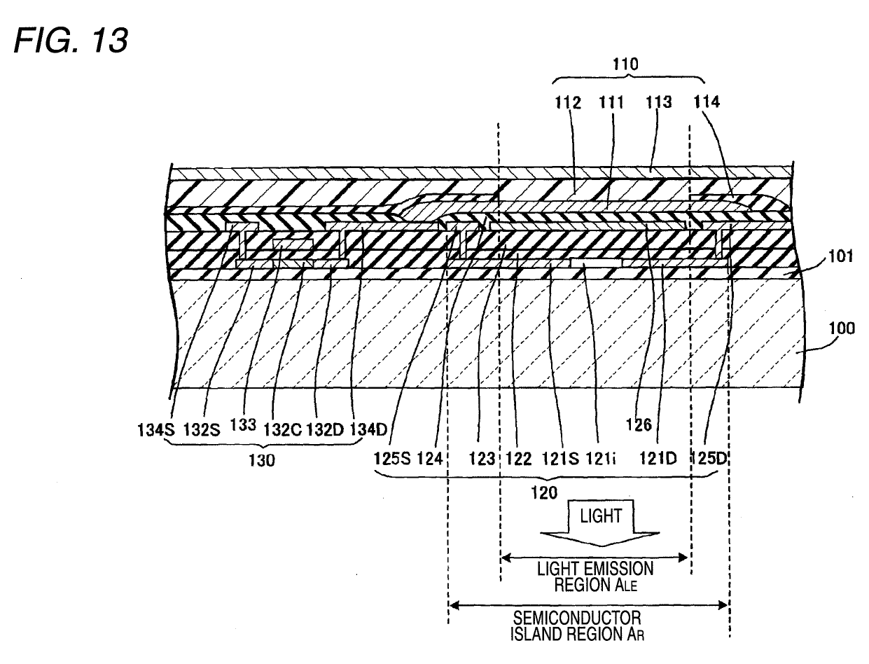

First, a first embodiment will be described. As shown in FIGS. 1A and 1B, a light emitting device according to the first embodiment is characterized in that a light detection element 120 and a light emitting element 110 are formed on a transmissive substrate 100 so as to be laminated on the transmissive substrate 100 (for example, refer to FIG. 13 for a specific laminated state), light is extracted from the transmissive substrate 100 side, and a control gate 126 is provided at a side above the light detection element 120, that is, a side opposite the transmissive substrate 100. The light detection element 120 is configured to include: source and drain regions 121S and 121D that are n-type impurity doped regions formed by injecting impurity ions into an island region 121 formed of polycrystalline silicon; a channel region 121i that is a non-doped i layer located between the source and drain regions 121S and 121D; and the transmissive control gate 126 that is formed on a surface of the island region with a gate insulating layer 203 formed of a silicon oxide layer interposed therebetween. The control gate 126 is formed of ITO (indium tin oxide) or doped polycrystalline silicon. In addition, the control gate 126 is formed of a metal, such as Cr, Mo, or Al in the case when transmittance is not required. The control gate 126 is formed to have a width enough to cover approximately the channel region 121i over the entire channel width of the light detection element 120.

FIG. 1B is a cross-sectional view taken along the line IB-IB of FIG. 1A. Source and drain electrodes 125S and 125D formed of polycrystalline silicon are formed above the source and drain regions 121S and 121D, respectively, and the control gate 126 and the source and drain electrodes 125S and 125D are disposed on the same side with respect to the channel region 121i, thereby forming a so-called coplanar structure.

The light emitting element 110 will be described later (for example, refer to FIG. 13), and a detailed explanation thereof will be omitted herein. The light emitting element 110 is formed by laminating an anode 111 serving as a first electrode, which is made of ITO (indium tin oxide), a pixel regulating unit 114 (an insulating layer that specifies a light emission region), a light emitting layer 112, and a cathode 113 serving as a second electrode in this order. Although the size of the anode 111 is shown in a square shape, a light emission region A_{LE} where actual light emission is performed corresponds to the size of an opening of the pixel regulating unit 114 of the light emitting element 110.

According to the configuration described above, since the control gate 126 is formed on the i layer that forms the channel region 121i of a thin film transistor, the electric potential of the i layer is uniquely determined by the control gate 126. As a result, since it is possible to stabilize the amount of electric charges generated in the i layer, the characteristics of a sensor can be stabilized. In addition, the control gate 126 does not exist on the source and drain regions 121S and 121D, which are regions where there is no control gate 126. Since the source and drain regions 121S and 121D are opposite to the anode 111 of the light emitting element 110, the source and drain regions 121S and 121D have electric potentials depending on the electric potential of the anode 111. For this reason, a charge transport characteristic is changed due to influence of the electric potential of the anode 111. However, since the amount of change is not so large compared with variation in the amount of electric charges generated in the channel region 121i in the known configuration, there is little influence on the change in detected current.

Moreover, since light from the light emitting element is emitted toward the transmissive substrate 100 side through the control gate (gate electrode), it is preferable that the control gate 126 be formed of a transmissive material. However, in the case when the width of a control gate is small, a small amount of light emitted from the light emitting element is blocked even if the control gate 126 is formed of a light shielding material. Accordingly, there is no large influence on the amount of emitted light. In addition, since it is also possible to use reflection from a base layer on a transmissive electrode in order to secure the amount of light emitted toward a light detection element, the control gate 126 may be formed of a light shielding (reflective) material.

However, in this structure, unevenness resulting from the control gate is formed inside a light emission region (luminous region) on the light emitting element 120 side, which causes variation in the thickness of the light emitting layer. As a result, a problem occurs in that uniformity of light emission easily deteriorates.

### Second Embodiment

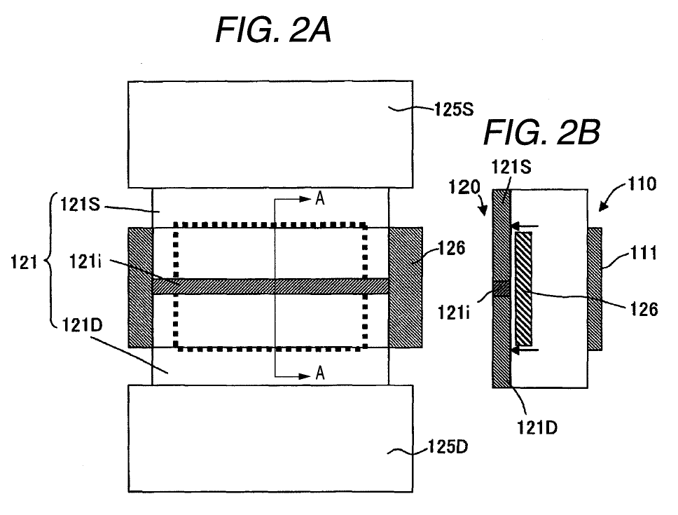

A second embodiment is characterized in that the control gate 126 is formed to cover a part of the source and drain regions 121S and 121D as shown in FIGS. 2A and 2B, while the control gate 126 is formed only on the channel region 121i so as to have a width enough to cover the channel region 121i in the first embodiment.

Moreover, in this configuration, an outer edge of the control gate 126 is located further inward than an outer edge of the anode 111 (and a light emission region A_{LE}: a region enclosed by a dotted line in FIG. 2A) of the light emitting element 110. FIG. 2B is a cross-sectional view taken along the line IIB-IIB of FIG. 2A. A light emitting device according to the second embodiment is formed in the same manner as the light emitting device according to the first embodiment except for the size of the control gate 126. In addition, the source and drain electrode electrodes 125S and 125D made of polycrystalline silicon are formed in the vicinity of the source and drain regions 121S and 121D, respectively.

According to the configuration described above, since the control gate 126 is formed on an i layer that forms the channel region 121i of a thin film transistor, the electric potential of the i layer is uniquely determined by the control gate 126. As a result, since it is possible to stabilize the amount of electric charges generated in the i layer, the characteristics of a sensor can be stabilized. Further, the source and drain regions 121S and 121D are almost covered by the control gate 126, and a region opposite the anode 111 of the light emitting element 110 is only an end region. The end region has an electric potential depending on the electric potential of the anode 111. For this reason, a charge transport characteristic is changed due to influence of the electric potential of the anode 111. However, since the amount of change is not so large compared with variation in the amount of electric charges generated in the channel region 121i in the known configuration, there is little influence on the change in detected current.

Furthermore, in the same manner as in the first embodiment, light from the light emitting element 110 is also emitted toward the transmissive substrate 100 side through the control gate 126 in the present embodiment. Accordingly, it is preferable that the control gate 126 be formed of a transmissive material. However, in the case when the width of the control gate 126 is small, detection of light may be performed by using reflection from a base layer on a transmissive electrode. Accordingly, in this case, the control gate 126 may be formed of a reflective material.

However, even in this structure, unevenness resulting from an edge of the control gate is formed inside a light emission region (luminous region) on the light emitting element 120 side, which causes variation in the thickness of the light emitting layer As a result, a problem occurs in that uniformity of light emission easily deteriorates.

### Third Embodiment

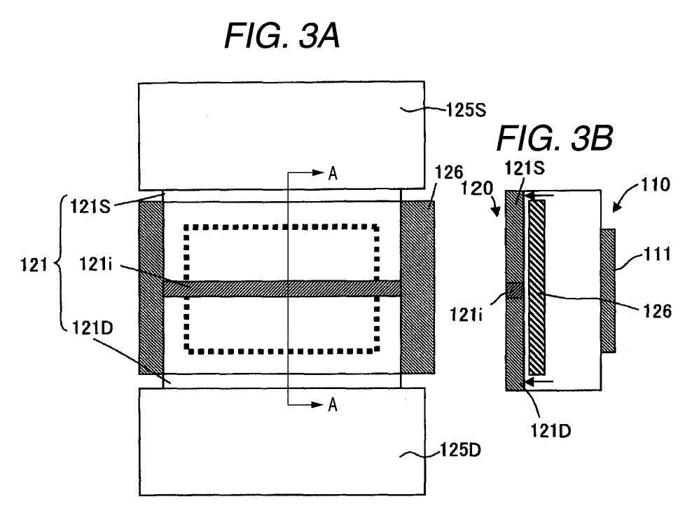

A third embodiment is characterized in that the control gate 126 is formed to cover a region that is larger than the light emission region A_{LE} (region enclosed by a dotted line in FIG. 3A) of the light emitting element 110 and includes the channel region 121i as shown in FIGS. 3A and 3B, while the control gate 126 is formed to cover only the channel region 121i in the first embodiment. Moreover, in this configuration, an outer edge of the control gate 126 is located further outward than an outer edge of the anode 111 of the light emitting element 110.

FIG. 3B is a cross-sectional view taken along the line IIIB-IIIB of FIG. 3A. In addition, the source and drain electrodes 125S and 125D made of polycrystalline silicon are formed in the vicinity of the source and drain regions 121S and 121D, respectively. A light emitting device according to the third embodiment is formed in the same manner as the light emitting devices according to the first and second embodiments except for the size of the control gate 126.

According to the configuration described above, since the control gate 126 is formed on an i layer that forms the channel region 121i of a thin film transistor, the electric potential of the i layer is uniquely determined by the control gate 126. In addition, since the outer edge of the control gate 126 is located further outward than the outer edge of the anode 111, the electric potential of a thin film transistor that forms the light detection element 120 is decided by a gate potential independently from the electric potential of the anode 111. Therefore, it is possible to stabilize the characteristics of a sensor. In addition, since the source and drain regions 121S and 121D are entirely covered by the control gate 126, there is no region directly opposite the anode 111 of the light emitting element 110.

Furthermore, in the same manner as in the first embodiment, light from the light emitting element 110 is also emitted toward the transmissive substrate 100 side through the control gate 126 in the present embodiment. Accordingly, it is necessary to form the control gate 126 using a transmissive material. In addition, the control gate 126 needs to be formed of a transmissive material in order to detect the amount of light using the light detection element 120 and from a point of view that light having passed through the control gate 126 needs to be received in the i layer.

Moreover, in this configuration, the outer edge of the control gate 126 is located further outward than the outer edge of the anode 111 of the light emitting element 110 and is located further outward than an outer edge of the light emission region A_{LE}. In this structure, unevenness resulting from the control gate is not formed inside the light emission region A_{LE} (luminous region) on the light detection element 120 side (that is, a lower part of the light emission region A_{LE} is planarized by the control gate 126), unlike the first and second embodiments. Accordingly, since variation in the thickness of the light emitting layer does not occur, uniformity of light emission is secured.

In addition, a transmissive layer may be formed on the entire surface of a substrate so as to serve as a uniform control gate. In this case, since a photolithographic process for patterning is not needed due to integrated formation, unevenness is not formed on the surface. As a result, since the light emitting layer can be made uniform, it becomes possible to provide a light emitting device that has a long life time and a stable light emitting characteristic. In addition, an effect on the process that a rate of disconnection of the control gate 126 occurring due to the unevenness of a thin film transistor decreases is also acquired by uniform formation.

### Fourth Embodiment

Next, a light emitting device having a bottom emission and bottom gate structure according to a fourth embodiment of the invention will be described. In the first to third embodiments, the light emitting device having a bottom emission and top gate structure has been described. However, in the following fourth to sixth embodiments, a light emitting device having a bottom emission and bottom gate structure in which the control gate 126 is provided at the transmissive substrate 100 side, that is, at a side opposite the light emitting element 110 will be described.

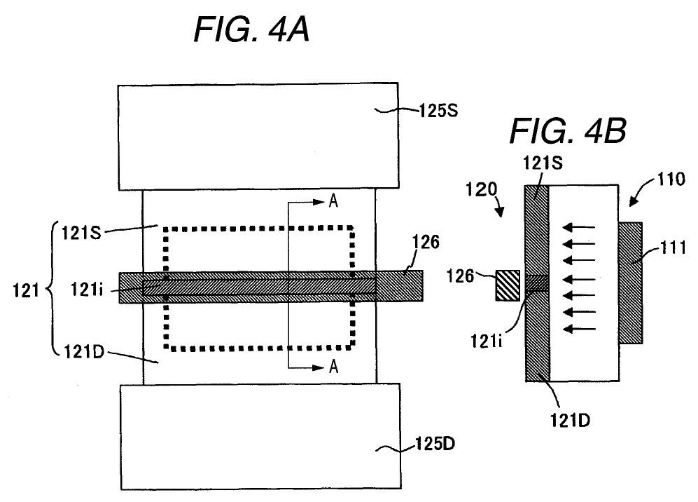

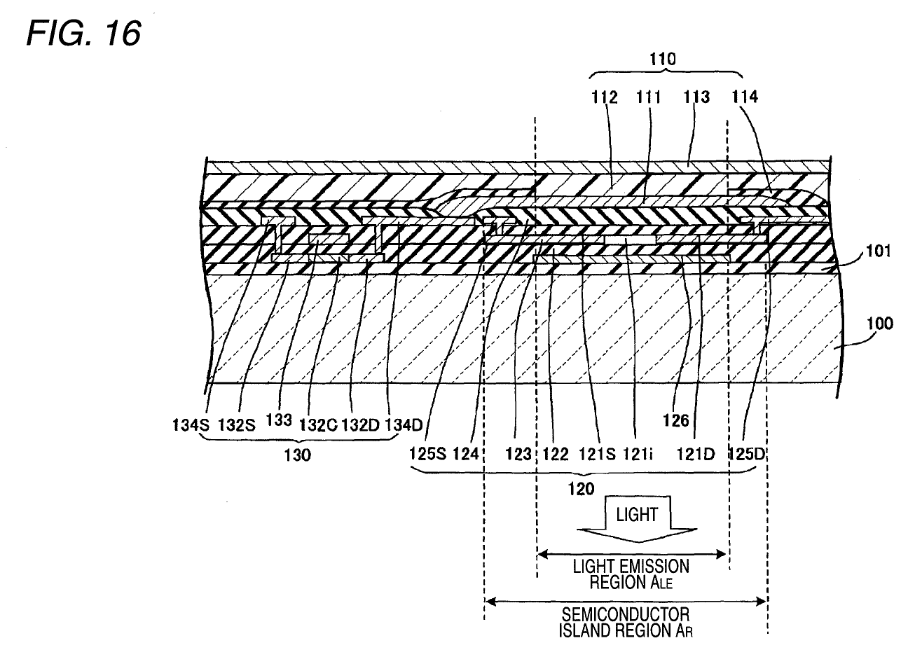

As shown in FIGS. 4A and 4B, the light emitting device is formed by forming the control gate 126 on the transmissive substrate 100 with a top coat (not shown) interposed therebetween and providing a polycrystalline silicon layer 121, which forms source and drain regions 121S and 121D of a thin film transistor and a channel region 121i, on the control gate 126. Further, in the same manner as in the first embodiment, the light detection element 120 and the light emitting element 110 are laminated and light is extracted from the transmissive substrate 100 side. However, the fourth embodiment is different from the first embodiment in that the transmissive control gate 126 is disposed at a lower layer side of a silicon island region that forms the source and drain regions 121S and 121D and the channel region 121i of the light detection element 120, that is, the transmissive control gate 126 is disposed at the transmissive substrate 100 side (refer to FIG. 16 for a laminated state; in this case, the width of the control gate 126 is different from that in FIG. 16, as shown below).

The control gate 126 is formed of indium tin oxide or doped polycrystalline silicon and is formed to have a width enough to cover approximately the channel region 121i over the entire channel width of the light detection element 120.

FIG. 4B is a cross-sectional view taken along the line IVB-IVB of FIG. 4A. Source and drain electrodes 125S and 125D formed of polycrystalline silicon are formed above the source and drain regions 121S and 121D, respectively, and the control gate 126 (gate electrode) and the source and drain electrodes 125S and 125D are disposed on the opposite sides with respect to the channel region 121i, thereby forming an inverse-staggered structure.

The light emitting device according to the fourth embodiment is the same as the light emitting device according to the first embodiment except for the location of the control gate 126.

According to the configuration described above, since the control gate 126 is formed below an i layer that forms the channel region 121i of a thin film transistor, the electric potential of the i layer is uniquely determined by the electric potential of the anode 111 and the control gate 126. At this time, since the control gate 126 is located sufficiently close to the i layer, which forms the channel region 121i, compared with the anode 111, the electric potential of the control gate 126 becomes dominant. Accordingly, it is possible to stabilize the characteristics of a sensor by means of the electric potential of the control gate 126. In addition, the control gate 126 does not exist on the source and drain regions 121S and 121D, which are regions where there is no control gate 126. Since the source and drain regions 121S and 121D are opposite to the anode 111 of the light emitting element 110, the source and drain regions 121S and 121D have electric potentials depending on the electric potential of the anode 111. For this reason, a charge transport characteristic is changed due to influence of the electric potential of the anode 111. However, since the amount of change is not so large compared with variation in the amount of electric charges generated in the channel region 121i in the known configuration, there is little influence on the change in detected current.

Moreover, since light from the light emitting element 110 is emitted toward the transmissive substrate 100 side through the control gate, it is preferable that the control gate 126 be formed of a transmissive material. However, in the case when the width of the control gate is small, a small amount of light emitted from the light emitting element is blocked even if the control gate 126 is formed of a light shielding material. Accordingly, there is no large influence on the amount of emitted light. Furthermore, in order to secure the amount of light emitted toward the light detection element 120, it is also possible to use light reflected from the control gate 126 in addition to reflection from a base layer on a transmissive electrode. Accordingly, it is possible to increase the sensitivity of the light detection element 120 by forming the control gate 126 with a reflective material.

However, in this structure, unevenness resulting from the control gate is formed inside a light emission region (luminous region) on the light emitting element 120 side, which causes variation in the thickness of the light emitting layer. As a result, a problem occurs in that the uniformity of light emission easily deteriorates.

### Fifth Embodiment

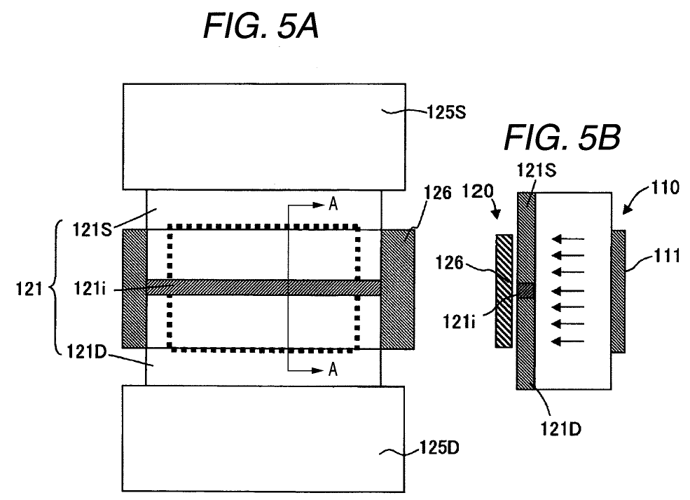

A fifth embodiment is characterized in that the control gate 126 is formed to cover the source and drain regions 121S and 121D as shown in FIGS. 5A and 5B, while the control gate 126 is formed only below the channel region 121i so as to have a width enough to cover the channel region 121i in the fourth embodiment.

Moreover, in this configuration, an outer edge of the control gate 126 is located further inward than an outer edge of the anode 111 of the light emitting element 110 and located further inward than an outer edge of the light emission region A_{LE} (a region enclosed by a dotted line in FIG. 5A) of the light emitting element 110.

FIG. 5B is a cross-sectional view taken along the line VB-VB of FIG. 5A. In addition, the source and drain electrodes 125S and 125D made of polycrystalline silicon are formed in the vicinity of the source and drain regions 121S and 121D, respectively. A light emitting device according to the fifth embodiment is formed in the same manner as the light emitting device according to the fourth embodiment except for the size of the control gate 126.

According to the configuration described above, since the control gate 126 is formed below an i layer that forms the channel region 121i of a thin film transistor, an electric potential of the i layer is uniquely determined by the control gate 126. As a result, since it is possible to stabilize the amount of electric charges generated in the i layer, characteristics of a sensor can be stabilized. In addition, since the source and drain regions 121S and 121D are almost covered by the control gate 126, only an end region opposite the anode 111 of the light emitting element 110 is not affected by the electric potential of the control gate 126. The end region has an electric potential depending on the electric potential of the anode 111. For this reason, a charge transport characteristic is changed due to influence of the electric potential of the anode 111, but a distance from the anode 111 may be large. Accordingly, since the amount of change is not so large compared with variation in the amount of electric charges generated in the channel region 121i in the known configuration, there is little influence on the change in detected current.

Furthermore, in the same manner as in the first embodiment, light from the light emitting element 110 is also emitted toward the transmissive substrate 100 side through the control gate 126 in the present embodiment. Accordingly, it is preferable that the control gate 126 be formed of a transmissive material. However, in the case when the width of the control gate 126 is small, detection of light may be performed by using reflection from the control gate 126 and a base layer on a transmissive electrode. Accordingly, in this case, the control gate 126 may be formed of a reflective material.

However, even in this structure, unevenness resulting from an edge of the control gate is formed inside a light emission region (luminous region) on the light emitting element 120 side, which causes variation in the thickness of the light emitting layer. As a result, a problem occurs in that the uniformity of light emission easily deteriorates.

### Sixth Embodiment

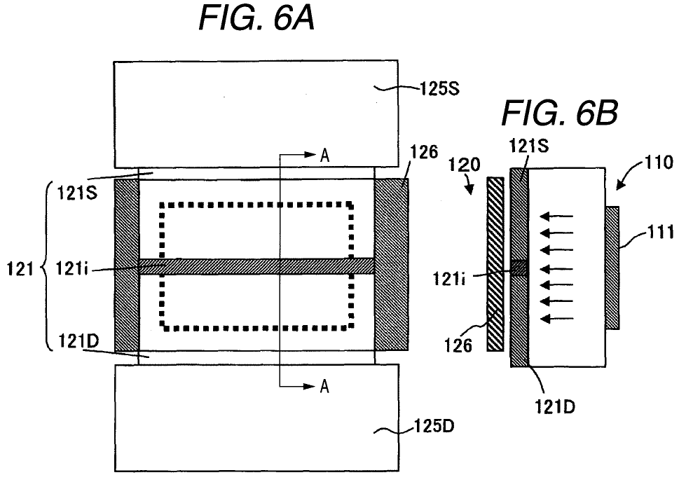

A sixth embodiment is characterized in that the control gate 126 is formed to cover a region that is larger than the anode 111 (light emission region) of the light emitting element 111 and includes the channel region 121i as shown in FIGS. 6A and 6B, while the control gate 126 is formed to cover only the channel region 121i in the fourth embodiment. Moreover, in this configuration, an outer edge of the control gate 126 is located further outward than an outer edge of the anode 111 of the light emitting element 110.

FIG. 6B is a cross-sectional view taken along the line VIB-VIB of FIG. 6A. In addition, the source and drain electrodes 125S and 125D made of polycrystalline silicon are formed in the vicinity of the source and drain regions 121S and 121D, respectively. A light emitting device according to the sixth embodiment is formed in the same manner as the light emitting devices according to the fourth and fifth embodiments except for the size of the control gate 126.

According to the configuration described above, since the control gate 126 is formed to cover an i layer that forms the channel region 121i of a thin film transistor, the electric potential of the i layer is uniquely determined by the control gate 126. In addition, since an outer edge of the control gate 126 is located further outward than an outer edge of the anode 111, the electric potential of the entire thin film transistor that forms the light detection element 120 is decided by a gate potential independently from the electric potential of the anode 111. As a result, since it is possible to stabilize the amount of electric charges generated in the i layer, characteristics of a sensor can be stabilized. In addition, since the source and drain regions 121S and 121D are entirely covered by the control gate 126, there is no region directly opposite the anode 111 of the light emitting element 110.

Furthermore, in the same manner as in the first embodiment, light from the light emitting element 110 is emitted toward the transmissive substrate 100 side through the control gate 126 in the present embodiment. Accordingly, it is necessary to form the control gate 126 using a transmissive material. In addition, the control gate 126 needs to be formed of a transmissive material in order to detect the amount of light using the light detection element 120 and from a point of view that light having passed through the control gate 126 needs to be received in the i layer.

According to the configuration described above, unevenness is not formed inside the light emission region A_{LE} (a region enclosed by a dotted line in FIG. 6A). Accordingly, since the uniformity of a light emitting layer can be maintained, it is possible to obtain a satisfactory emission characteristic.

Moreover, in this configuration, the outer edge of the control gate 126 may be configured to be located further inward than the outer edge of the anode 111 of the light emitting element 110 and located further outward than the outer edge of the light emission region A_{LE}. In this case, the light emission region A_{LE} is not regulated by the anode 111 but a range thereof is determined by the pixel regulating unit 114 that covers a part of the anode 111, which will be described later (refer to FIG. 16).

In addition, a transmissive layer may be formed on the entire surface of a substrate so as to serve as a uniform control gate. In this case, since a photolithographic process for patterning is not needed due to integrated formation, unevenness is not formed on the surface. As a result, since the light emitting layer can be made uniform, it becomes possible to provide a light emitting device that has a long life time and a stable light emitting characteristic.

### Seventh Embodiment

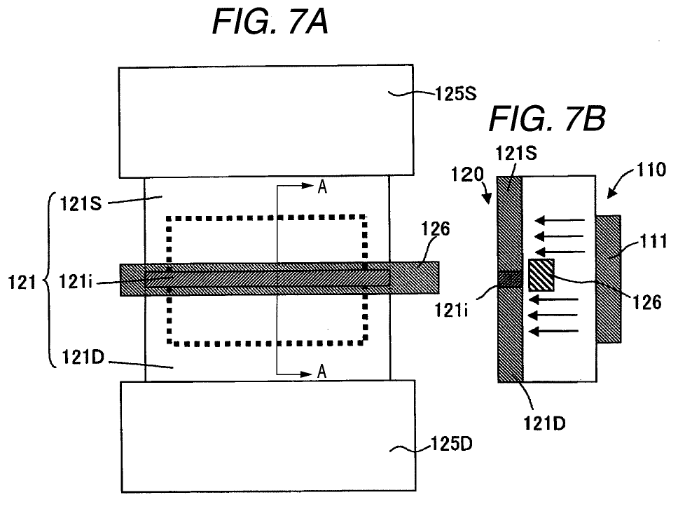

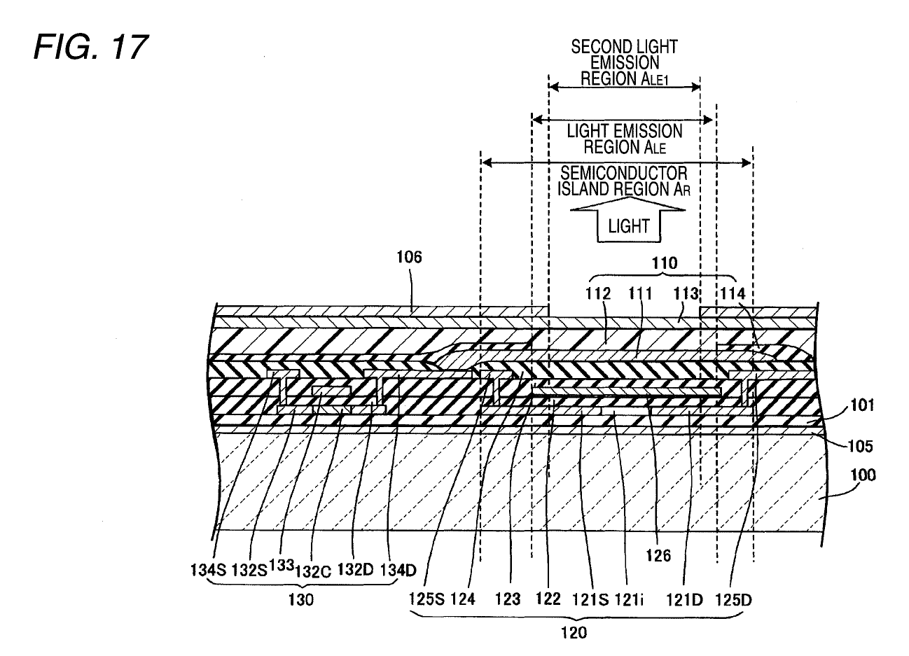

In the first to sixth embodiments, the bottom emission type light emitting devices have been described. However, in the following seventh to twelfth embodiments, a so-called top emission type light emitting device in which light is extracted toward a side opposite a substrate will be described. As shown in FIGS. 7A and 7B, the light emitting device is a top emission type light emitting device in which the cathode 113 (refer to FIG. 17) of a light emitting element is also formed of a transmissive material, which is different from the bottom emission type light emitting devices described above. The light emitting element is formed in the same manner as the light emitting device, which is shown in FIGS. 1A and 1B, according to the first embodiment except that a reflective layer is formed on the transmissive substrate 100 and emitted light is extracted upward although not shown herein.

Operations and effects are also similar to those described above. According to the configuration, since the control gate 126 is formed on an i layer that forms the channel region 121i of a thin film transistor, the electric potential of the i layer is uniquely determined by the control gate 126. Therefore, it is possible to stabilize the characteristics of a sensor. In addition, the control gate 126 does not exist on the source and drain regions 121S and 121D, which are regions where there is no control gate 126. Since the source and drain regions 121S and 121D are opposite to the anode 111 of the light emitting element 110, the source and drain regions 121S and 121D have electric potentials depending on the electric potential of the anode 111. For this reason, a charge transport characteristic is changed due to influence of the electric potential of the anode 111. However, since the amount of change is not so large compared with variation in the amount of electric charges generated in the channel region 121i in the known configuration, there is little influence on the change in detected current.

In addition, since light from the light emitting element 110 is emitted upward, the control gate 126 does not almost have an influence on emitted light. In addition, since it is also possible to use reflection from a base layer on a transmissive electrode in order to secure the amount of light emitted toward the light detection element 120, the control gate 126 may be formed of a light shielding (reflective) material.

### Eighth Embodiment

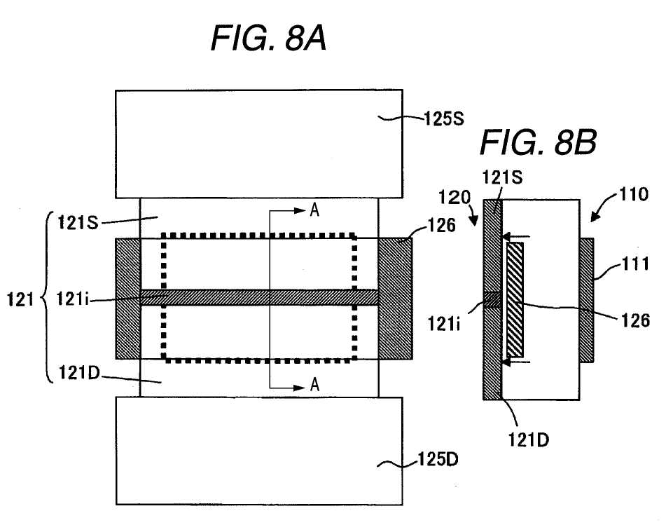

An eighth embodiment is characterized in that the control gate 126 is formed to cover the source and drain regions 121S and 121D as shown in FIGS. 8A and 8B, while the control gate 126 is formed only on the channel region 121i so as to have a width enough to cover the channel region 121i in the seventh embodiment. Moreover, in this configuration, an outer edge of the control gate 126 is located further inward than an outer edge of the anode 111 (and the light emission region A_{LE}) of the light emitting element 110.

FIG. 8B is a cross-sectional view taken along the line VIIIB-VIIIB of FIG. 8A. In addition, the source and drain electrodes 125S and 125D made of polycrystalline silicon are formed in the vicinity of the source and drain regions 121S and 121D, respectively. A light emitting device according to the eighth embodiment is formed in the same manner as the light emitting device according to the seventh embodiment except for the size of the control gate 126.

According to the configuration described above, since the control gate 126 is formed on an i layer that forms the channel region 121i of a thin film transistor, the electric potential of the i layer is uniquely determined by the control gate 126. Therefore, it is possible to stabilize the characteristics of a sensor. Further, since the source and drain regions 121S and 121D are almost covered by the control gate 126, a region opposite the anode 111 of the light emitting element 110 is only an end region. The end region has an electric potential depending on the electric potential of the anode 111. For this reason, a charge transport characteristic is changed due to influence of the electric potential of the anode 111. However, since the amount of change is not so large compared with variation in the amount of electric charges generated in the channel region 121i in the known configuration, there is little influence on the change in detected current.

In addition, even in the present embodiment, light from the light emitting element 110 is emitted upward in the same manner as in the seventh embodiment. Accordingly, the control gate 126 does not almost have an influence on emitted light. In addition, since it is also possible to use reflection from a base layer on a transmissive electrode in order to secure the amount of light emitted toward the light detection element 120, the control gate 126 may be formed of a light shielding (reflective) material.

### Ninth Embodiment

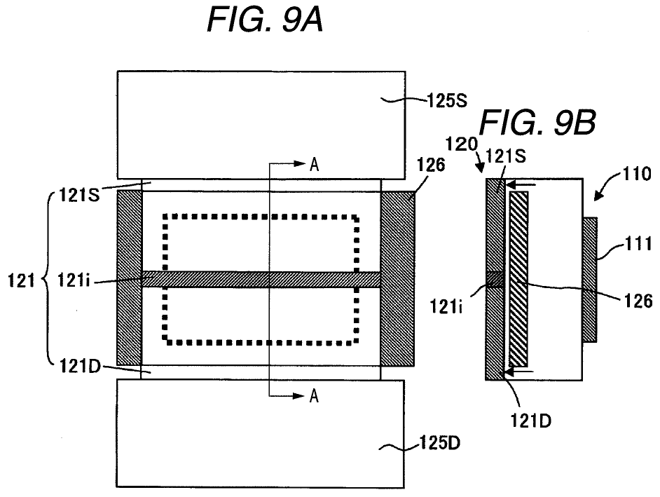

A ninth embodiment is characterized in that the control gate 126 is formed to cover a region that is larger than the light emission region A_{LE} (region enclosed by a dotted line in FIG. 9A) of the light emitting element 110 and includes the channel region 121i as shown in FIGS. 9A and 9B, while the control gate 126 is formed to cover only the channel region 121i in the seventh embodiment.

Moreover, in this configuration, an outer edge of the control gate 126 is located further outward than an outer edge of the anode 111 of the light emitting element 110.

FIG. 9B is a cross-sectional view taken along the line IXB-IXB of FIG. 9A. In addition, the source and drain electrodes 125S and 125D made of polycrystalline silicon are formed in the vicinity of the source and drain regions 121S and 121D, respectively. A light emitting device according to the ninth embodiment is formed in the same manner as the light emitting devices according to the seventh and eighth embodiments except for the size of the control gate 126.

According to the configuration described above, since the control gate 126 is formed on an i layer that forms the channel region 121i of a thin film transistor, the electric potential of the i layer is uniquely determined by the control gate 126. In addition, since the outer edge of the control gate 126 is located further outward than the outer edge of the anode 111, the electric potential of the entire thin film transistor that forms the light detection element 120 is decided by a gate potential independently from the electric potential of the anode 111. Therefore, it is possible to stabilize the characteristics of a sensor. In addition, since the source and drain regions 121S and 121D are entirely covered by the control gate 126, there is no region directly opposite the anode 111 of the light emitting element 110.

In addition, even in the present embodiment, light from the light emitting element 110 is emitted upward in the same manner as in the eighth embodiment. Accordingly, the control gate 126 does not almost have an influence on emitted light, but it is essential that the control gate 126 is transmissive in order to secure the amount of light emitted toward the light detection element 120.

According to the configuration described above, unevenness is not formed inside the light emission region A_{LE}. Accordingly, since the uniformity of a light emitting layer can be maintained, it is possible to obtain a satisfactory emission characteristic.

Moreover, in this configuration, the outer edge of the control gate 126 is located further outward than the outer edge of the anode 111 of the light emitting element 110 and is located further outward than an outer edge of the light emission region A_{LE}. In this structure, unevenness resulting from the control gate is not formed inside the light emission region A_{LE} (luminous region) on the light detection element 120 side (that is, a lower part of the light emission region A_{LE} is planarized by the control gate 126), unlike the seventh and eighth embodiments. Accordingly, since variation in the thickness of the light emitting layer does not occur, uniformity of light emission is secured.

### Tenth Embodiment

Next, a light emitting device having a top emission and bottom gate structure according to a tenth embodiment of the invention will be described. In the seventh to ninth embodiments, the light emitting device having a top emission and top gate structure has been described. However, in the following tenth to twelfth embodiments, a light emitting device having a top emission and bottom gate structure in which the control gate 126 is provided at the transmissive substrate 100 side, that is, at a side opposite the light emitting element 110 will be described.

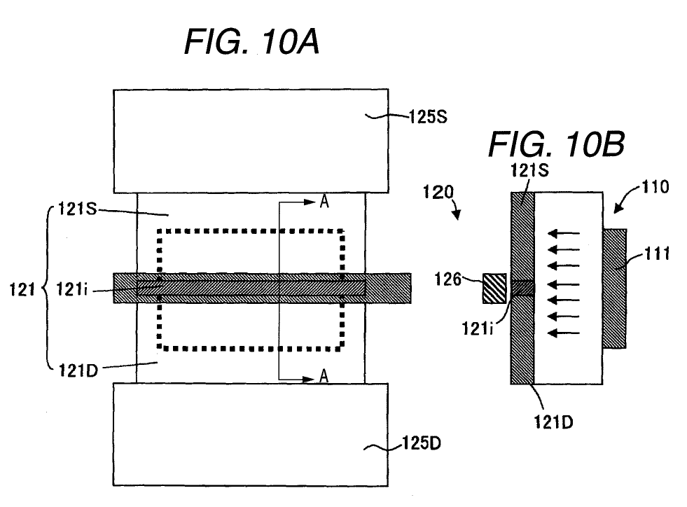

As shown in FIGS. 10A and 10B, the light emitting device is formed by forming the control gate 126 on the transmissive substrate 100 with a top coat (not shown) interposed therebetween and providing a polycrystalline silicon layer 121, which forms source and drain regions 121S and 121D of a thin film transistor and a channel region 121i, on the control gate 126. Further, in the same manner as in the seventh embodiment, the light detection element 120 and the light emitting element 110 are laminated and light is extracted from the side opposite the transmissive substrate 100 side. However, the tenth embodiment is different from the seventh embodiment in that the control gate 126 is disposed at a lower layer side of a silicon island region that forms the source and drain regions 121S and 121D and the channel region 121i of the light detection element 120, that is, the control gate 126 is disposed at the transmissive substrate 100 side. The control gate 126 is formed of indium tin oxide or doped polycrystalline silicon and is formed to have a width enough to cover approximately the channel region 121i over the entire channel width of the light detection element 120.

FIG. 10B is a cross-sectional view taken along the line XB-XB of FIG. 10A. In addition, the source and drain electrodes 125S and 125D made of polycrystalline silicon are formed in the vicinity of the source and drain regions 121S and 121D, respectively.

The light emitting device according to the tenth embodiment is the same as the light emitting device according to the seventh embodiment except for the location of the control gate 126.

According to the configuration described above, since the control gate 126 is formed below an i layer that forms the channel region 121i of a thin film transistor, the electric potential of the i layer is uniquely determined by the electric potential of the anode 111 and the control gate 126. At this time, since the control gate 126 is located sufficiently close to the i layer, which forms the channel region 121i, compared with the anode 111, the electric potential of the control gate 126 becomes dominant. Accordingly, it is possible to stabilize the characteristics of a sensor by means of the electric potential of the control gate 126.

Furthermore, in the present embodiment, light from the light emitting element 110 is emitted upward and the control gate is located at the rear side of the light detection element. Accordingly, unlike the first to ninth embodiments described above, the control gate 126 does not have an influence on emitted light and does not have an influence on the light detection element. For this reason, the control gate 126 may have a transmissive property or a light shielding property. However, in order to secure the amount of light emitted toward the light detection element 120, it is preferable to have a reflective property.

However, in this structure, unevenness resulting from the control gate is formed inside a light emission region (luminous region) on the light emitting element 120 side, which causes variation in the thickness of the light emitting layer. As a result, a problem occurs in that the uniformity of light emission easily deteriorates.

### Eleventh Embodiment

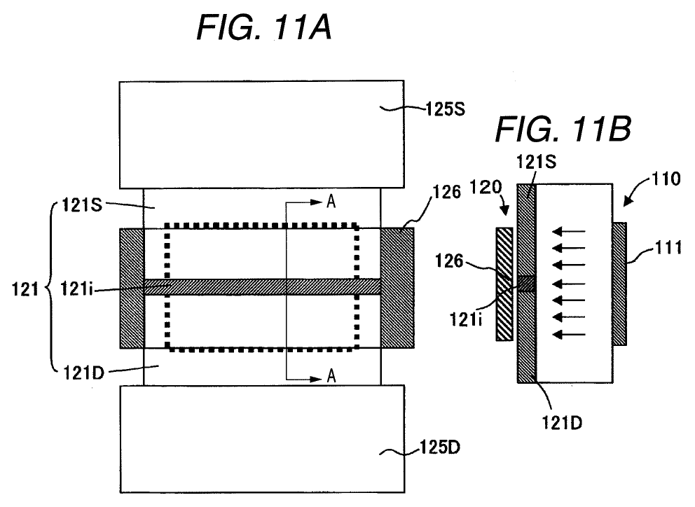

An eleventh embodiment is characterized in that the control gate 126 is formed to cover the source and drain regions 121S and 121D as shown in FIGS. 11A and 11B, while the control gate 126 is formed only below the channel region 121i so as to have a width enough to cover the channel region 121i in the tenth embodiment. Moreover, in this configuration, an outer edge of the control gate 126 is located further inward than an outer edge of the anode 111 of the light emitting element 110 and an outer edge of the light emission region A_{LE} (a region enclosed by a dotted line in FIG. 11A) of the light emitting element 110.

FIG. 11B is a cross-sectional view taken along the line XIB-XIB of FIG. 11A. In addition, the source and drain electrodes 125S and 125D made of polycrystalline silicon are formed in the vicinity of the source and drain regions 121S and 121D, respectively. A light emitting device according to the eleventh embodiment is formed in the same manner as the light emitting device according to the tenth embodiment except for the size of the control gate 126.

According to the configuration described above, since the control gate 126 is formed below an i layer that forms the channel region 121i of a thin film transistor, the electric potential of the i layer is uniquely determined by the control gate 126. Therefore, it is possible to stabilize the characteristics of a sensor. In addition, since the source and drain regions 121S and 121D are almost covered by the control gate 126, only an end region opposite the anode 111 of the light emitting element 110 is not affected by the electric potential of the control gate 126. The end region has an electric potential depending on the electric potential of the anode 111. For this reason, a charge transport characteristic is changed due to influence of the electric potential of the anode 111, but a distance from the anode 111 may be large. Accordingly, since the amount of change is not so large compared with variation in the amount of electric charges generated in the channel region 121i in the known configuration, there is little influence on the change in detected current.

In addition, even in the present embodiment, light from the light emitting element 110 is emitted upward in the same manner as in the tenth embodiment. Accordingly, a material of the control gate 126 does not matter. However, even in this case, the control gate 126 is preferably formed of a reflective material in order to secure the amount of light emitted toward the light detection element 120.

However, even in this structure, unevenness resulting from an edge of the control gate is formed inside a light emission region (luminous region) on the light emitting element 120 side, which causes variation in the thickness of the light emitting layer. As a result, a problem occurs in that the uniformity of light emission easily deteriorates.

### Twelfth Embodiment

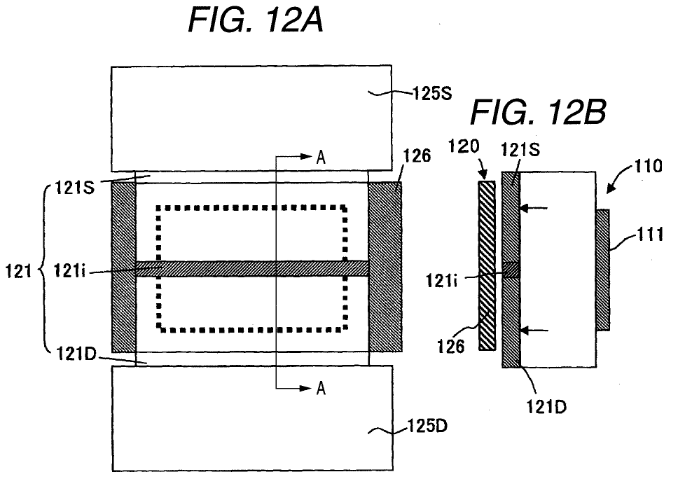

A twelfth embodiment is characterized in that the control gate 126 is formed to cover a region that is larger than the anode 111 (light emission region) of the light emitting element 111 and includes the channel region 121i as shown in FIGS. 12A and 12B, while the control gate 126 is formed to cover only the channel region 121i in the tenth embodiment. Moreover, in this configuration, an outer edge of the control gate 126 is located further outward than an outer edge of the anode 111 of the light emitting element 110.

FIG. 12B is a cross-sectional view taken along the line XIIB-XIIB of FIG. 12A. In addition, the source and drain electrodes 125S and 125D made of polycrystalline silicon are formed in the vicinity of the source and drain regions 121S and 121D, respectively. A light emitting device according to the twelfth embodiment is formed in the same manner as the light emitting devices according to the tenth and eleventh embodiments except for the size of the control gate 126.

According to the configuration described above, since the control gate 126 is formed below the entire thin film transistor, the electric potential of the i layer is uniquely determined by the control gate 126. In addition, since an outer edge of the control gate 126 is located further outward than an outer edge of the anode 111 and the control gate 126 exists at the position much closer than the anode 111, the electric potential of the entire thin film transistor that forms the light detection element 120 is decided by a gate potential independently from the electric potential of the anode 111. Therefore, it is possible to stabilize the characteristics of a sensor.

In addition, even in the present embodiment, a material of the control gate 126 does not matter in the same manner as in the eleventh embodiment. More preferably, a reflective electrode is used to secure the amount of light emitted toward the light detection element 120.

Moreover, a reflective layer may be formed on the entire surface of the substrate, such that both a reflection function and an electric potential control function are realized. In this case, since a photolithographic process for patterning is not needed due to integrated formation, unevenness is not formed on the surface. As a result, since the light emitting layer can be made uniform, it becomes possible to provide a light emitting device that has a long life time and a stable light emitting characteristic.

Further, even in the present embodiment, it is possible to prevent the number of processes from increasing by forming the light detection element 120 in the same process as other functional elements. For example, a case in which the light detection element 120 is realized by using a thin film transistor formed in the same process as a thin film transistor (TFT) forming a driving circuit is assumed. In this structure, the light detection element 120 having the control gate 126 below the channel region 121i of the thin film transistor can be obtained by forming a metal thin film or the like on a surface of the glass substrate 100. Accordingly, the electric potential of the channel is not affected by the electric potential of a transmissive electrode that is located at the substrate side of the electroluminescent element with an interlayer insulating layer interposed therebetween, and an electric field is applied to the channel by the control gate 126. Thus, characteristics of a thin film transistor serving as the light detection element are controlled by a gate-source voltage V_{GS}.

As described above in the first to twelfth embodiments, it is possible to prevent the number of processes from increasing by forming the light detection element according to the embodiments of the invention in the same process as other functional elements. For example, a case in which the light detection element is realized by using a thin film transistor formed in the same process as a thin film transistor (TFT) forming a driving circuit is assumed. In this structure, the control gate of the light detection element is formed above or below the channel region of the thin film transistor. Accordingly, the electric potential of the channel is not affected by the electric potential of the transmissive electrode that is located at the substrate side of the electroluminescent element with an interlayer insulating layer interposed therebetween, and an electric field is applied to the channel by the control gate. Thus, the characteristics of the thin film transistor serving as the light detection element are controlled by the gate-source voltage V_{GS}. In the thin film transistor serving as the light detection element, a fluctuation in output is large in a region, in which a current flows by photoelectric conversion, due to characteristics of the transistor. For this reason, it is known that measurement in a region where a current does not flow, that is, an OFF region is effective. Therefore, it becomes possible to improve precision of detection of the amount of light by controlling the thickness or a material of an interlayer insulating layer, which is to be a gate insulating layer, such that the control gate of the thin film transistor operates effectively.

In the first to twelfth embodiments, an example in which the light detection element 120 is formed using a thin film transistor has been explained. However, other thin film devices such as a photodiode, a FET formed within a semiconductor substrate, a junction type transistor, and the like may be used without being limited to the thin film transistor. In addition, an example using a PIN diode will be described as a fifth example later.

In addition, it is general that a first electrode formed at the light detection element 120 side of the electroluminescent element is the anode 111 and is formed of an electrode material having transmittance, but it is needless to say that the first electrode may be the cathode 113.

Hereinafter, examples of the invention will be described in detail.

### FIRST EXAMPLE

In a first example of the invention, a structure of the light emitting device having a bottom emission and top gate structure, which was explained in the first to third embodiments, will be described.

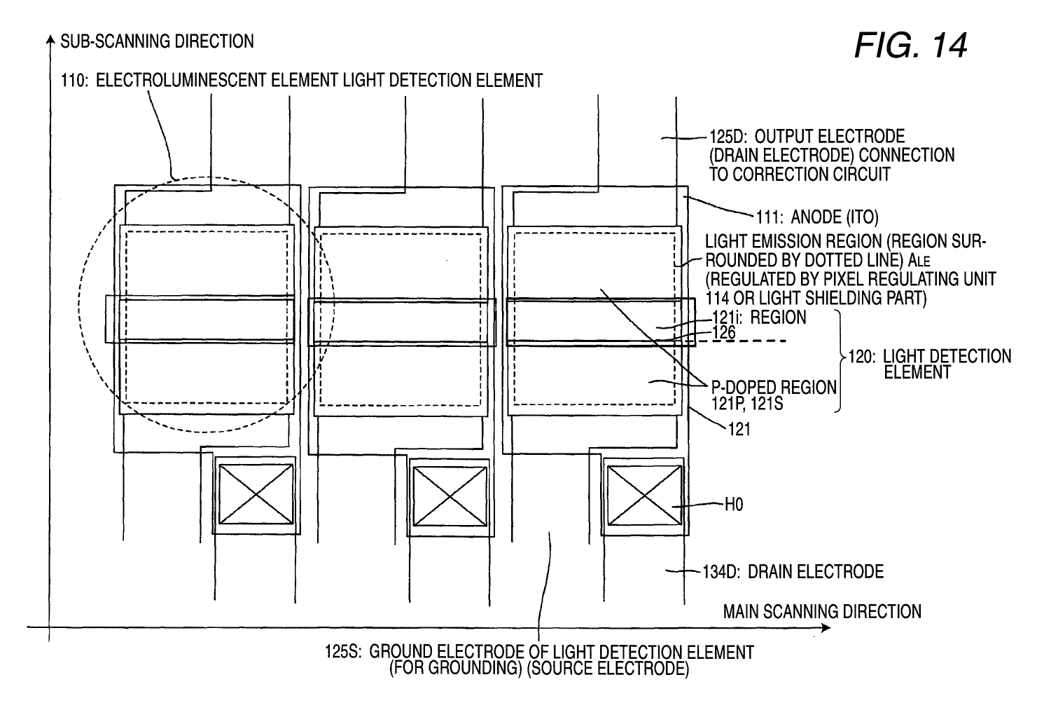

FIG. 13 is a cross-sectional view illustrating the configuration of a light emitting device, which is used in an optical head provided in an exposure unit of an image forming apparatus, in the first example of the invention, and FIG. 14 is a top view illustrating main parts of the light emitting device. In the first example, there is provided a light emitting device in which an electroluminescent element 110 serving as a light source is laminated on a light detection element 120 with a control gate 126 interposed therebetween, and the electric potential of a channel region 121i of a thin film transistor that forms the light detection element is controlled by a control gate and is not affected by the electric potential of an anode of the electroluminescent element 110. As shown in FIG. 14, the light emitting device is formed such that the electroluminescent element 110 is laminated on a thin film transistor (TFT), which forms the light detection element 120 formed on a substrate, and an outer edge of the island region 121 that is formed of a polycrystalline silicon and forms an element region of the light detection element 120 becomes an outside of the light emission region A_{LE} of the electroluminescent element. In the light emitting device, the control gate 126 is smaller than the anode 111 but is disposed to reliably cover the channel region 121i, such that the electric potential of the channel region 121i is reliably controlled.

If the configuration of the light emitting device in the first example is simply expressed, it can be said that the electroluminescent element 110 is laminated directly on a main surface of the light detection element 120 so as to overlap the light emission region A_{LE} of the electroluminescent element 110.

As is apparent from FIG. 14, in the island region 121 of the light detection element 120 obtained as a result of forming a step difference, an outer edge of an element region A_{R} is formed to be an outside of the light emission region A_{LE} of the electroluminescent element. In addition, there is no step difference in a region corresponding to a light detection region of the electroluminescent element, and a base of the light emitting layer forms a flat surface. Accordingly, in a light emission region which is to be an effective region of an optical head, a light emitting layer of the optical head is uniformly formed.

That is, as shown in FIG. 13, in the light emitting device in this example, the light detection element 120 having the control gate 126 and the electroluminescent element 110 are sequentially laminated on the glass substrate 100 where a base coat layer 101 for planarization is formed on a surface, and a thin film transistor serving as a switching transistor 130 for driving the electroluminescent element while correcting a driving current or a driving time in accordance with an output of the light detection element 120 and a driving circuit 140, which serves as a chip IC, connected to the thin film transistor are mounted. In addition, in the light detection element 120, the source region 121S and the drain region 121D are formed by doping the island region A_{R}, which is formed of a polycrystalline silicon layer formed on a surface of the base coat layer 101, in a desired concentration under a condition in which the island region A_{R} is spaced apart from a channel region formed of a strip-shaped i layer. In addition, the light detection element 120 is configured to include source and drain electrodes 125S and 125D formed of a polycrystalline silicon layer that is formed to penetrate a first insulating layer 122 and a second insulating layer 123, which are silicon oxide layers formed on the source and drain regions 121S and 121D, using a through hole and the control gate 126 formed of ITO. In addition, the electroluminescent element 110 is formed on the layer obtained as the above result with a silicon nitride layer serving as a protective layer 124 interposed therebetween. Specifically, an ITO (indium tin oxide) 111, which is to be an anode serving as a first electrode, a pixel regulating unit 114, a light emitting layer 112, and a cathode 113 serving as a second electrode are laminated in this order. Here, the insulating layer (pixel regulating unit) 114 for defining a light emission region is formed on the anode 111.

On the other hand, each of the layers that form the light detection element 120 is formed in the same manufacturing process as the selection transistor 130 serving as a driving transistor. That is, source and drain regions 132S and 132D are formed with a channel region 132C interposed therebetween in the same process as a semiconductor island of a light detection element, and source and drain electrodes 134S and 134D being in contact therewith are laminated. The source and drain electrodes 134S and 134D and a gate electrode 133 form a thin film transistor serving as a selection transistor.

Each of the layers is formed using typical semiconductor processes, such as formation of a semiconductor thin film using a CVD method, a sputtering method, and a vacuum deposition method, polycrystallization using annealing, patterning using photolithography, etching, injection of impurity ions, and formation of an insulating layer and a metal layer.

Here, the glass substrate 100 is a transparent and colorless plate. As the glass substrate 100, inorganic glasses including inorganic oxide glasses, such as a soda lime glass, a glass containing barium and strontium, a lead glass, an aluminosilicate glass, a borosilicate glass, a barium borosilicate glass, and a quartz glass which are transparent or translucent, and inorganic fluoride glasses can be used. In the case of forming a TFT on a surface, a borosilicate glass represented by #1737 manufactured by Corning, Inc. is generally used in many cases.

Other materials may also be used for the glass substrate 100. For example, polymer films that use polymeric materials, such as transparent or translucent polyethylene terephthalate, polycarbonate, polymethylmethacrylate, polyethersulfone, polyvinyl fluoride, polypropylene, polyethylene, polyacrylate, amorphous polyolefin, fluorine-based resin polysiloxane, and polysilane may be used. In addition, chalcogenide glasses, such as transparent or translucent As₂S₃, As₄₀S₁₀, and S₄₀Ge₁₀, and metal oxides and metal nitrides, such as ZnO, Nb₂O, Ta₂O₅, SiO, Si₃N₄, HfO₂, and TiO₂, may be used. In the case of extracting light emitted from a luminous region without involving a substrate, semiconductor materials such as opaque silicon, germanium, silicon carbide, gallium arsenide, and gallium nitride, or the above-described transparent substrate materials containing a pigment and the like, or metal materials whose surfaces are subjected to insulation processing can also be appropriately selected. Alternatively, a laminated substrate obtained by laminating a plurality of substrate materials may also be used.

In addition, resistors, capacitors, inductors, diodes, transistors, and the like for driving the electroluminescent element 110 may be integrated on a surface of a substrate, such as the glass substrate 100, or within the substrate in order to form a circuit, which will be described later.

In addition, according to uses, a material that allows only light having a specific wavelength to be transmitted therethrough, a material that has a light-to-light conversion function and makes a conversion into light having a specific wavelength, and the like may be used. In addition, preferably, a substrate having an insulation property is used. However, the substrate is not limited thereto. For example, the substrate may have conductivity as long as the conductivity does not prevent driving of the electroluminescent element 110 or according to uses.

The base coat layer 101 is formed on the glass substrate 100. The base coat layer 101 is configured to include two layers of a first layer formed of SiN and a second layer formed of SiO₂. Each of the layers made of SiN and SiO₂ is preferably formed using a sputtering method or a CVD method, even though each of the layers may be formed using a vacuum deposition method and the like.

The selection transistor 130 of the electroluminescent element 110 and the light detection element 120 are formed on the base coat layer 101 using a polycrystalline silicon layer formed in the same process. A circuit for driving the electroluminescent element 110 is configured to include circuit elements, such as resistors, capacitors, inductors, diodes, and transistors, wiring lines used for electrical connection among the circuit elements, and contact holes. However, taking into consideration of miniaturization of an optical head, it is preferable to use a thin film transistor. In the first example, the light detection element 120 is located between the electroluminescent element 110 including the light emitting layer 112 and the glass substrate 100, which is an output surface of light, and the element region A_{R} of the light detection element 120 is larger than the light emission region A_{LE}, as is apparent from FIG. 13. In addition, since the light emission region A_{LE} exists inside the control gate 126 of the light detection element 120, a material that does not allow light to be transmitted therethrough cannot be used for the light detection element 120. Accordingly, a transparent material should be used for the control gate (gate electrode), the channel region 121i, and the source and drain regions 121S and 121D of the light detection element 120 in order that light output from the light emitting layer 112 is not blocked. As the transparent material of the light detection element 120, it is desirable to select polycrystalline silicon, for example.

In the first example, the selection transistor 130 and the light detection element 120 are formed on the same layer by forming a uniform semiconductor layer on the base coat layer 101 and then performing pattern etch (etching) processing on the semiconductor layer. Processing for collectively forming metal layers of the selection transistor 130 and the light detection element 120, which are independent from each other in an island shape, from the same metal layer is advantageous in reducing the number of manufacturing processes and a manufacturing cost. In addition, in the light detection element 120, the element region A_{R} where light output from the light emission region A_{LE} is received corresponds to a surface of polycrystalline silicon or amorphous silicon that is to be the light detection element 120 and has an island shape.

On the light detection element 120 and the selection transistor 130 for applying an electric field to the light emitting layer 112 of the electroluminescent element 110, the control gate 126 is formed with the first insulating layer 122 and the second insulating layer 123 formed of silicon oxide layers interposed therebetween. The electric potential of the channel region 121i may be controlled independently from the electric potential of the anode 111 by controlling the electric potential of the control gate. In contrast, in the case when the control gate 126 does not exist, the first insulating layer 122, the second insulating layer 123, and the protective layer 124 formed of silicon oxide layers operate as gate insulating layers between the ITO 111, which serves as an anode of an electroluminescent element, and the source and drain regions 121S and 121D and the channel region 121i. Moreover, a voltage drop from the electric potential of the ITO is determined by a voltage drop depending on the layer thickness, and the electric potential of the channel region 121i depends on the electric potential of the anode 111. For example, the first insulating layer 122 and the second insulating layer 123 (and the protective layer 124) that form the gate insulating layer are formed of SiO₂ or SiN by using the vacuum deposition method, the sputtering method, or the CVD method.

In addition, a gate electrode 131 is formed on a surface of the first insulating layer 122 serving as a gate insulating layer located immediately above the selection transistor 130. For example, a metal material, such as Cr and Al, is used as a material of the gate electrode 131. In addition, in the case when the transmittance is required for a gate electrode, ITO or a laminated structure of ITO and a thin metal layer is used for a gate electrode. The gate electrode 131 is formed using the vacuum deposition method, the sputtering method, the CVD method, and the like.

The second insulating layer 123 is formed on the substrate surface formed with the gate electrode 131. The second insulating layer 123 is formed on the entire surface of a laminate body formed until now.

On the second insulating layer, the drain electrode 125D serving as an output electrode of a light detection element, the source electrode 125S serving as a ground electrode of the light detection element, the source electrode 134S, and the drain electrode 134D are formed in addition to the control gate 126 of the light detection element. The drain electrode 125D serving as the output electrode of the light detection element and the source electrode 125S serving as the ground electrode of the light detection element are connected to the source and drain regions 121S and 121D of the light detection element 120 and performs transmission of an electrical signal output from the light detection element 120 and grounding of the light detection element 120. The source electrode 134S and the drain electrode 134 are connected to the source and drain regions 132S and 132D of the selection transistor 130. An electric field is applied to the channel region 132C by applying an electric potential to the gate electrode 133 in a state where a predetermined electric potential difference is granted between the source and drain electrodes 134S and 134D, and the selection transistor 130 have a function as a switching element. As a result, the selection transistor 130 operates as a circuit that drives the electroluminescent element 110 serving as a light emitting element. As materials of the drain electrode 125D serving as the output electrode of the light detection element, the source electrode 125S serving as the ground electrode of the light detection element, and the source and drain electrodes 134S and 134D, for example, a metal such as Cr or Al is used. In addition, in the case when the transparency is required, ITO or a laminated structure of a thin metal layer and ITO is used.

As shown in FIG. 13, the drain electrode 125D serving as the output electrode of the light detection element and the ground electrode of the light detection element pass through the first insulating layer 122 and the second insulating layer 123 so as to be electrically connected to the light detection element 120. Similarly, the source electrode 134S and the drain electrode 134D also pass through the first insulating layer 122 and the second insulating layer 123 so as to be electrically connected to the selection transistor 130. Therefore, a through hole for connecting the drain electrode 125D serving as the output electrode of the light detection element and the source electrode 125S serving as the ground electrode of the light detection element with the light detection element 120 and a through hole for connecting the source and drain electrodes 134S and 134D with the selection transistor 130 need to be provided in the first insulating layer 122 and the second insulating layer 123 before forming the drain electrode 125D serving as the output electrode of the light detection element, the source electrode 125S serving as the ground electrode of the light detection element, and the source and drain electrodes 134S and 134D.

The through holes have depths until a surface of the light detection element 120 and a surface of the selection transistor 130 are exposed, that is, a contact surface of the light detection element 120, the drain electrode 125D serving as the output electrode of the light detection element, and the source electrode 125S serving as the ground electrode of the light detection element and a contact surface of the selection transistor 130, the source electrode 134S, and the drain electrode 134D are exposed. In addition, the through holes are provided immediately above ends of the light detection element 120 and the selection transistor 130 by etching processing and the like. A halogen-based etching gas is used for etching. Through holes of the first insulating layer 122 and the second insulating layer 123 are opened by introducing an etching gas under a state in which a surface is covered with a resist pattern formed with openings using photolithography and performing patterning. At this time, a material that does not cause chemical reaction with materials used to form the light detection element 120 and the selection transistor 130 is selected as an etching gas.

After processing for exposing the contact surface of the drain electrode 125D serving as the output electrode of the light detection element, the source electrode 125S serving as the ground electrode of the light detection element, and the light detection element 120 and the contact surface of the source and drain electrodes 134S and 134D and the selection transistor 130 is completed, the drain electrode 125D serving as the output electrode of the light detection element, the source electrode 125S serving as the ground electrode of the light detection element, and the drain electrode 134D are formed. The source and drain electrodes 134S and 134D are obtained by uniformly forming a metal layer to be a sensor electrode on a surface of the second insulating layer 123, surfaces of the above-described through holes, and a contact surface of both sensor electrodes, the surface of the light detection element 120, and the selection transistor 130, then performing etching on the metal layer, and then dividing the uniform metal layer into the drain electrode 125D serving as the output electrode of the light detection element, the source electrode 125S serving as the ground electrode of the light detection element, and the source and drain electrodes 134S and 134D.

After the drain electrode 125D serving as the output electrode of the light detection element, the source electrode 125S serving as the ground electrode of the light detection element, and the source and drain electrodes 134S and 134D are formed, the protective layer 124 is formed. For example, the protective layer 124 is formed using the vacuum deposition method, the sputtering method, the CVD method, and the like.

The anode 111 is formed on the protective layer 124. The anode 111 is formed of ITO (indium tin oxide), for example. As a constituent material of the anode 111, IZO (zinc doped indium oxide), ATO (Sb doped SnO₂), AZO (Al doped ZnO), ZnO, SnO₂, In₂O₃, and the like may be used in addition to ITO. As shown in FIG. 13, the anode 111 is formed on the surface of the protective layer 124 that is located immediately above the light detection element 120. As shown in FIG. 13, the anode 111 passes through the protective layer 124 so as to be electrically connected to the drain electrode 134D. Accordingly, it is necessary to provide a through hole for connecting the anode 111 and the drain electrode 134D to the protective layer 124 before formation the anode 111. This through hole has a depth until a surface of the drain electrode 134D, that is, a contact surface of the drain electrode 134D and the anode 111 are exposed and is provided immediately above an end of the drain electrode 134D by etching processing and the like. After the etching processing is performed, a layer corresponding to the anode 111 is formed. Although the anode 111 may be formed using the vacuum deposition method or the like, it is preferable to form the anode 111 using the sputtering method or the CVD method in order to obtain the precise anode 111 having satisfactory resistance and transmittance. In addition, in the first example, ITO is used for the anode 111.

After forming the anode 111, a silicon nitride layer is formed as the pixel regulating unit 114. As a material of the silicon nitride layer as the pixel regulating unit 114, it is desirable to use a material which is high in insulation property and strong against dielectric breakdown, indicates satisfactory film formation, and is easily patterned. In the first example, silicon nitride and aluminium nitride are used as a material used to form the silicon nitride layer serving as the pixel regulating unit 114. The silicon nitride layer serving as the pixel regulating unit 114 is provided between the anode 111 and the light emitting layer 112. The silicon nitride layer as the pixel regulating unit 114 serves to insulate the light emitting layer 112 located outside the light emission region A_{LE} from the anode 111 and regulates a place where the light emitting layer 112 emits light. Accordingly, a region of the light emitting layer 112 overlapping the silicon nitride layer serving as the pixel regulating unit 114 corresponds to a non-luminous region, and a region of the light emitting layer 112 not overlapping the silicon nitride layer serving as the pixel regulating unit 114 corresponds to the light emission region A_{LE}. The silicon nitride layer serving as the pixel regulating unit 114 is configured to regulate such that the light emission region A_{LE} of the light emitting layer 112 is smaller than the element region A_{R} of the light detection element 120 and the light emission region A_{LE} is disposed inside the element region A_{R} of the light detection element 120.

After forming the silicon nitride layer as the pixel regulating unit 114, the light emitting layer 112 is formed. The light emitting layer 112 is formed using an inorganic luminescent material or polymer-based or small-molecule-based organic luminescent materials, which will be explained in detail below. As inorganic luminescent materials used to form the light emitting layer 112, it is possible to use titanium•potassium phosphate, barium•boron oxide, lithium•boron oxide, and the like. As a polymer-based organic luminescent material used to form the light emitting layer 112, a material having fluorescence or phosphorescence characteristics in a visible region is preferable. For example, a polymer-based luminescent material formed of poly(para-phenylenevinylene) (PPV), polyfluorene, or a derivative thereof may be used. Moreover, in addition to Alq₃ or Be-benzoquinolinol (BeBq₂), fluorescent whitening agents of benzoxazole family, such as 2,5-bis(5,7-di-t-pentyl-2-benzoxazolyl)-1,3,4-thiadiazole, 4,4′-bis(5,7-pentyl-2-benzoxazolyl)stilbene, 4,4′-bis[5,7-di-(2-methyl-2-butyl)-2-benzoxazolyl]stilbene, 2,5-bis(5,7-di-t-pentyl-2-benzoxazolyl)thiophene, 2,5-bis([5-α,α-dimethylbenzyl]-2-benzoxazolyl)thiophene, 2,5-bis[5,7-di-(2-methyl-2-butyl)-2-benzoxazolyl]-3,4-diphenylthiophene, 2,5-bis(5-methyl-2-benzoxazolyl)thiophene, 4,4′-bis(2-benzoxazolyl)biphenyl, 5-methyl-2-[2-[4-(5-methyl-2-benzoxazolyl)phenyl]vinyl]benzoxazolyl, and 2-[2-(4-chlorophenyl)vinyl]naphtha[1,2-d]oxazole; of benzothiazole family, such as 2,2′-(p-phenylenedivinylene)-bisbenzothiazole; and of benzoimidazole family, such as 2-[2-[4-(2-benzoimidazolyl)phenyl]vinyl]benzoimidazole and 2-[2-(4-carboxyphenyl)vinyl]benzoimidazole; or 8-hydroxyquinoline-based metal complexes such as tris(8-quinolinol)aluminum, bis(8-quinolinol)magnesium, bis(benzo[f]-8-quinolinol)zinc, bis(2-methyl-8-quinolinorato)aluminum oxide, tris(8-quinolinol)indium, tris(5-methyl-8-quinolinol)aluminum, 8-quinolinollithium, tris(5-chloro-8-quinolinol)gallium, bis(5-chloro-8-quinolinol)calcium, and poly[zinc-bis(8-hydroxy-5-quinolinol)methane]; metal chelated oxinoid compounds such as dilithiumepindolidione; styrylbenzene-based compounds such as 1,4-bis(2-methylstyryl)benzene, 1,4-bis(3-methylstyryl)benzene, 1,4-bis(4-methylstyryl)benzene, distyrylbenzene, 1,4-bis(2-ethylstyryl)benzene, 1,4-bis(3-ethylstyryl)benzene, 1,4-bis(2-methylstyryl)-2-methylbenzene and 1,4-bis(2-methylstyryl)-2-ethylbenzene; distyrylpyrazine derivatives such as 2,5-bis(4-methylstyryl)pyrazine, 2,5-bis(4-ethylstyryl)pyrazine, 2,5-bis[2-(1-naphthyl)vinyl]pyrazine, 2,5-bis(4-methoxystyryl)pyrazine, 2,5-bis[2-(4-biphenyl)vinyl]pyrazine and 2,5-bis[2-(1-pyrenyl)vinyl]pyrazine; or naphthalimde derivatives, perylene derivatives, oxadiazole derivatives, aldazine derivatives, cyclopentadiene derivatives, styrylamine derivatives, coumarin-based derivatives, aromatic dimethylidene derivatives, or the like are used as the small-molecule-based organic luminescent materials used to form the light emitting layer 112. Furthermore, anthracene, salicylates, pyrene, chronene, and the like are also used. Alternatively, a phosphorescent luminescent material, such as fac-tris(2-phenylpyridine)iridium may also be used. The light emitting layer 112 made of a polymer-based material or a small-molecule-based material is obtained by forming a material dissolved in a solvent, such as toluene and xylene, in the layer shape by using wet film formation method, such as a spin coat method, an ink jet method, a gap coating method, and a printing method, and then drying the solvent in a solution. The light emitting layer 112 made of a small-molecule-based material is typically obtained by laminating a material using a vacuum deposition method, a vapor deposition and polymerization method, a CVD method, and the like. However, a method according to characteristics of a luminescent material may be selected to form the light emitting layer 112.

Although the light emitting layer 112 has been described as a single layer for the sake of convenience, the light emitting layer 112 may have a three-layered structure including a hole transport layer, an electron blocking layer, and the organic luminescent material layer (not shown) sequentially from the anode 111 side. Alternatively, the light emitting layer 112 may have a two-layered structure including an electron transport layer and the organic luminescent material layer (not shown) sequentially from the cathode 113 side, or the light emitting layer 112 may have a two-layered structure including a hole transport layer and the organic luminescent material layer (not shown) sequentially from the anode 111 side. Alternatively, the light emitting layer 112 may have a seven-layered structure including a hole injection layer, a hole transport layer, an electron blocking layer, an organic luminescent material layer, a hole blocking layer, an electron transport layer, and an electron injection layer (not shown) sequentially from the cathode 113 side. More simply, the light emitting layer 112 may also have a single-layered structure including only the organic luminescent material described above. Alternatively, the light emitting layer 112 may have a mixed layer obtained by mixing materials having respective functions or a structure obtained by laminating the mixed layers. As described above, in the first example, the light emitting layer 112 may have a multi-layered structure having function layers, such as a hole transport layer, an electron blocking layer, and an electron transport layer. The same is true for the other examples which will be described later.

As the hole transport layer among the function layers described above, a material which has high mobility of holes, is transparent, and indicates satisfactory film formation is preferable. In addition to TPD, organic materials including porphyrin compounds such as porphine, tetraphenylporphine copper, phthalocyanine, copper phthalocyanine, and titanium phthalocyanine oxide; aromatic tertiary amines such as 1,1-bis{4-(di-P-tolylamino)phenyl}chclohexane, 4,4′,4″-trimethyltriphenylamine, N,N,N′,N′-tetrakis(P-tolyl)-P-phenylenediamine, 1-(N,N-di-P-tolylamine)naphthalene, 4,4′-bisphenyl-4,4′-diaminobisphenyl, N,N′-diphenyl-N,N′-di-m-tolyl-4,4′-diaminobisphenyl, and N-phenylcarbazole; stilbene compounds such as 4-di-P-tolylaminostilbene and 4-(di-P-tolylamino)-4′-[4-(di-P-tolylamino)styryl]stilbene; triazole derivatives, oxadiazole derivatives, imidazole derivatives, polyarylalkane derivatives, pyrazoline derivatives, pyrazolone derivatives, phenylenediamine derivatives, anilamine derivatives, amino-substituted chalcone derivatives, oxazole derivatives, styrylanthracene derivatives, fluorenone derivatives, hydrazone derivatives, silazane derivatives, polysilane-aniline copolymers, high molecular weight oligomers, styrylamine compounds, aromatic dimethylidene-based compopunds, poly-3,4-ethylenedioxythiophene (PEDOT), tetradihexylfluorenylbiphenyl (TFB), or polythiophene derivatives known as poly-3-methylthiophene (PMeT), are used for the hole transport layer. In addition, a polymer-dispersed hole transport layer obtained by dispersing a small-molecule organic material for a hole transport layer in polymer, such as polycarbonate, may also be used. Furthermore, inorganic oxide, such as MoO₃, V₂O₅, WO₃, TiO₂, SiO, and MgO, may also be used. In addition, these hole transport materials may also be used as an electron blocking material.

As the electron transport layer among the function layers described above, Oxadiazole derivatives such as 1,3-bis(4-tert-butylphenyl-1,3,4-oxadiazolyl)phenylene (OXD-7); anthraquinodimethane derivatives, diphenylquinone derivatives, polymers comprising silol derivatives, or bis(2-methyl-8-quinolinorato)-(para-phenylphenolato)aluminum (BAlq), bathocuproine (BCP), and the like are used. In addition, these materials used to form the electron transport layer may also be used as a hole blocking material.

After forming the light emitting layer 112, the cathode 113 is formed. The cathode 113 is obtained by forming a metal, such as Al, in the layer shape using a vacuum deposition method and the like, for example. A metal or an alloy having a low work function is used for the cathode 113 of the organic electroluminescent element 110. For example, metals such as Ag, Al, In, Mg, and Ti, Mg alloys such as Mg—Ag alloy and Mg—In alloy, and Al alloys such as Al—Li alloy, Al—Sr alloy, Al—Ba alloy are used. Alternatively, a laminated structure of metals including a first electrode layer abutting an organic material layer formed of a metal, such as Ba, Ca, Mg, Li, and Cs, or fluoride and oxide of these metals, such as LiF or CaO, and a second electrode that is formed on the first electrode layer using a metal material, such as Ag, Al, Mg, and In, may also be used.

The optical head in the first example, which is shown in FIG. 13, adopts a method of outputting light from the selection transistor 130 side of an organic electroluminescent element. Such structure of the organic electroluminescent element is called a bottom emission. In the bottom emission structure, light is extracted from the glass substrate 100 side. Accordingly, as already described above, the light detection element 120 is preferably formed of a material having high transparency. For example, the light detection element 120 is formed of polycrystalline silicon (polysilicon). In the case of the light detection element 120 formed of polycrystalline silicon, there is a problem that a capability of generating a photocurrent is low as compared with that in the light detection element 120 formed of amorphous silicon. However, such problem can be solved, for example, by providing a capacitor (not shown) in the vicinity of the organic electroluminescent element 110, accumulating electric charges in the capacitor for a predetermined period of time on the basis of a current output from the light detection element 120, and providing a processing circuit that performs voltage conversion. The bottom emission structure is advantageous in that a manufacturing process is simple because it is easy to form an electrode (anode), which is located at a side toward which light is extracted, with a transparent material.

FIG. 14 is a plan view illustrating the configuration near a light detection element of an optical head in the first example of the invention.

As shown in FIG. 14, the optical head in the first example is formed by disposing the plurality of electroluminescent elements 110 in the main scanning direction (direction of a row of elements), and one light detection element 120 is disposed to correspond to one luminous region (light emission region A_{LE}). By adopting such structure, the amount of emitted light of each organic electroluminescent element 110 can be independently measured by the light detection element 120. That is, it becomes possible to measure the amount of light of the plurality of organic electroluminescent elements 110 at the same time. As a result, it is possible to greatly reduce the measuring time.

In FIG. 14, the relationship among the light detection element 120, the drain electrode 125D serving as an output electrode of a light detection element, the source electrode 125S serving as a ground electrode of a light detection element, the light emission region A_{LE}, the island region A_{R}, the ITO (indium tin oxide) 111 which is to be an anode of the light emitting layer 112, a contact hole H_{D}, and the drain electrode 134D is shown. The light detection element 120 is connected to the drain electrode 125D serving as the output electrode of the light detection element and the source electrode 125S serving as the ground electrode of the light detection element. The drain electrode 125D serving as the output electrode of the light detection element is an electrode serving to transmit an electrical signal, which is output from the light detection element 120 for the purpose of correction of light, to a correction circuit (not shown). A feedback signal generated by the correction circuit is determined on the basis of the electrical signal, and processing required for correction of light is performed on the basis of the feedback signal. In the first example, the amount of emitted light of each electroluminescent element 110 is corrected on the basis of the feedback signal, and a value of a current for driving each electroluminescent element 110 is controlled by a driver circuit (not shown). As described above, in the first example, the amount of emitted light is controlled on the basis of an output of the light detection element 120. However, it may be possible to perform a so-called PWM control in which a driving time of each electroluminescent element 110 is controlled on the basis of the feedback signal.

The source electrode 125S serving as a ground electrode of a light detection element is an electrode used to ground the light detection element 120. The ITO (indium tin oxide) 111, which is an anode of the electroluminescent element 110 serving as a light emitting element, is connected to the drain electrode 134D of the selection transistor 130, and the electroluminescent element 110 is controlled by the selection transistor 130 through the drain electrode 134D.

As shown in FIGS. 13 and 14, in the optical head in the first example, the light detection elements 120 that are formed in the island shape using polycrystalline silicon (polysilicon) are disposed in a row in the main scanning direction. In addition, in each electroluminescent element 110, the channel region 121i of the light detection element 120 is covered with the control gate 126, such that variation in the electric potential due to change in the electric potential of the anode 111 does not occur in the channel region 121i. In addition, the light detection element 120 having the element region A_{R} larger than the light emission region A_{LE} is disposed below the light emitting layer 112 where the light emission region A_{LE} is restricted by a silicon nitride layer serving as the pixel regulating unit 114. By making the element region A_{R} (island-shaped part of polycrystalline silicon formed in the island shape) of the light detection element 120 larger than the light emission region A_{LE}, a change in local layer thickness of the light emitting layer 112 can be suppressed. Accordingly, it is possible to suppress variation in a current flowing through the light emitting layer 112. As a result, it becomes possible to manufacture an optical head in which uniform distribution of emitted light and an improvement in life time are realized.

Moreover, since the element region A_{R} of the light detection element 120, which is mounted in the optical head in the first example and is formed in the island shape, is larger than a luminous region, that is, the light emission region A_{LE}, it is possible to efficiently convert output light from a light emitting layer into an electrical signal used for correction of light.

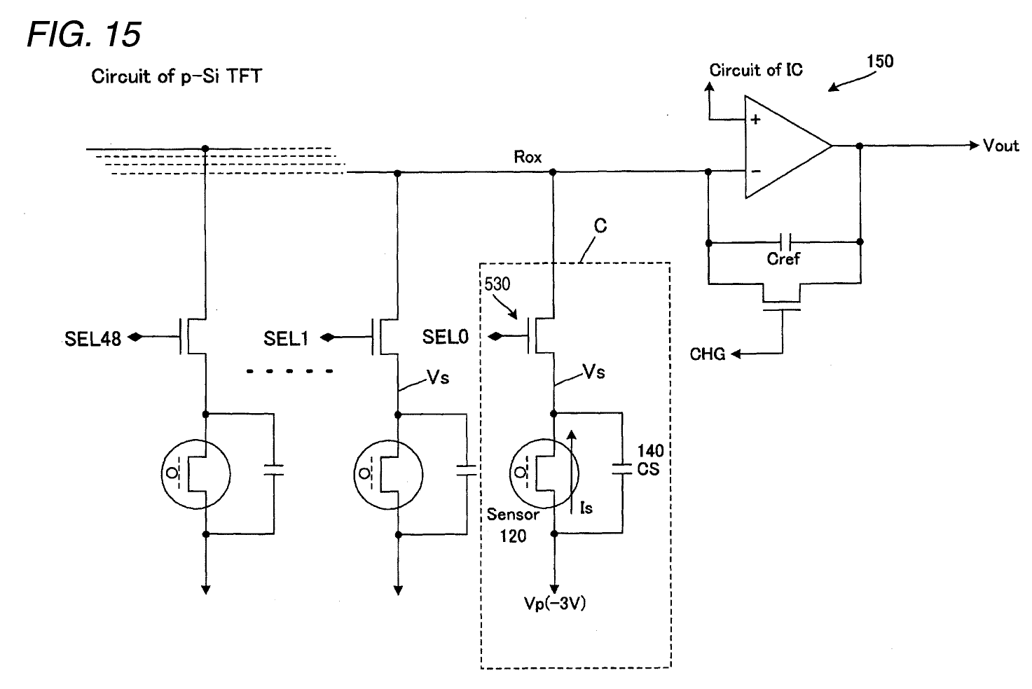

Next, a circuit for correcting the amount of light, which is used in the optical head of the invention, will be described. As shown by an equivalent circuit in FIG. 15, the circuit for correcting the amount of light is configured to include: a driver IC 150 provided with a charge amplifier; and a correction circuit unit C that is integrated in the glass substrate 100 so as to be connected to an input terminal of the driver IC 150. The correction circuit unit C is configured to include the switching transistor 530, the light detection element 120, and a capacitor that is connected in parallel with the light detection element 120 and charges an output current of the light detection element 120. Although not shown in the cross-sectional view of FIG. 13, the capacitor 140 is a conductive layer that is formed in the same process so as to be connected to the source and drain electrodes 134S and 134D of the light detection element and is formed by inserting the first and second insulating layers 122 and 123.

Here, the light detection element detects the amount of light by performing photoelectric conversion in the polycrystalline silicon layer (channel region) 121i using light from an electroluminescent element and then by taking out a current, which flows from a source region to a drain region, as a photocurrent. As described above, in this element, the ITO electrode 111 which is an anode of the electroluminescent element 110 is used as a gate electrode, and an electric field is applied to a polycrystalline silicon layer which is the channel region 121i of the light detection element by means of the electric potential of the gate electrode. However, since a distance between the light detection element and the control gate 126 is very short as compared with the electric field, the electric potential of the channel region 121i is determined by the electric potential of the control gate 126. As a result, a photoelectric conversion current flows. Therefore, an output that is highly precise and stable is obtained.

Thus, since the control gate 126 is disposed at the position closer than the ITO electrode 111 which is an anode of the electroluminescent element 110, the electric potential is applied to the polycrystalline silicon layer which is the channel region 121i of the light detection element 120 by means of the electric potential of the control gate 126. By controlling the electric potential of the control gate 126 so as to be driven in a region where the drain current becomes zero, it is possible to improve the precision of a photoelectric conversion current that is output as a sensor output from the drain electrode 125D to the correction circuit unit C (refer to FIG. 15). That is, the sensor output that is output from the drain electrode 125D is obtained by adding the drain current ID to an actual photoelectric conversion current. For this reason, it is preferable to use a thin film transistor in a region where a drain current of the thin film transistor is zero, that is, a region (OFF region) where an operation of the transistor is turned off. However, since the thin film transistor can be used in the OFF region by shifting the gate potential in the minus direction, a dark current can be neglected practically. According to the invention, it is important to detect a thin film transistor that forms the light detection element in an OFF state.

In addition, a state where the entire polycrystalline silicon layer, which is used as the channel region 121i of the thin film transistor that forms the light detection element, is completely covered with the ITO electrode which is an anode of the electroluminescent element is much effective in controlling a channel by means of the gate electric field.

In this example, a correction voltage is calculated on the basis of an output voltage of a light detection circuit in a light amount calculating circuit 150, a voltage applied to the anode 111 and the cathode 113 of the light emitting element is controlled by a driving circuit (not shown), a voltage is applied to the light emitting layer 112 formed between the anode 111 and the cathode 113 of the light emitting element, and a variation in amount of light of the light emitting element or a fluctuation in amount of light according to temporal change is compensated, such that uniform exposure is maintained.

Furthermore, as a modification of the first example of the invention, a light shielding layer that is a thin film using a chromium may be formed on a bottom surface of a glass substrate, such that a second light emission region is regulated by such openings. By forming the second light emission region smaller than an opening of a silicon nitride layer serving as the pixel regulating unit 114 described in the first example, a step difference part of the light emitting layer resulting from the silicon nitride layer can be removed from the light emission region. As a result, it becomes possible to make the light emitting layer more uniform. Other configurations are the same as those in the first example.

In the above description, DC driving has been applied to the organic electroluminescent element. However, an AC voltage, an AC current, or a pulse wave may be used to drive the organic electroluminescent element.

### SECOND EXAMPLE

In the second example of the invention, a structure of the light emitting device having a bottom emission and bottom gate structure, which was explained in the fourth to sixth embodiments, will be described.

In the bottom emission and bottom gate type light emitting device, the control gate of the bottom emission and top gate type light emitting device in the first example is disposed at the substrate side.

FIG. 16 is a cross-sectional view illustrating an optical head having a bottom emission and bottom gate structure. The second example is different from the first example in that the control gate 126 is formed on the cover coat 101 and faces the polycrystalline silicon layer (channel region) 121i with the first insulating layer 122 interposed therebetween such that the electric potential of the channel region 121i is controlled. In the same manner as in the first embodiment, the source and drain regions 121S and 121D are formed in the polycrystalline silicon layer with the channel region 121i interposed therebetween. However, only the following point is different. That is, the gate electrode 133 of the driving transistor 130 and the channel region 121i and the source and drain regions 121S and 121D, which are semiconductor regions of a thin film transistor that forms the light detection element, are formed on the same layer. In addition, a channel region 131i and source and drain regions 133S and 133D of the driving transistor 130 and the control gate 126 of the thin film transistor that forms the light detection element are formed on the same layer. Since those described above are all formed of a polycrystalline silicon layer, the light emitting device described above can be manufactured only by changing a mask used for photolithography without changing any process.

Here, the light detection element detects the amount of light by performing photoelectric conversion in the polycrystalline silicon layer (channel region) 121i using light from an electroluminescent element and then by taking out a current, which flows from a source region to a drain region, as a photocurrent. As described above, the ITO electrode 111 which is an anode of the electroluminescent element 110 is used as a gate electrode, and an electric field is applied to a polycrystalline silicon layer which is the channel region 121i of the light detection element by means of the electric potential of the gate electrode. However, since a distance between the light detection element and the control gate 126 is very short as compared with the electric field, the electric potential of the channel region 121i is determined by the electric potential of the control gate 126. Thus, it is possible to control the gate potential so as to be a region where the drain current 1D does not flow and detect a photoelectric conversion current that is highly precise and stable.

### THIRD EXAMPLE

In the third example of the invention, a structure of the light emitting device having a top emission and top gate structure, which was explained in the seventh to ninth embodiments, will be described.

FIG. 17 is a cross-sectional view illustrating an optical head having a top emission structure. In the top emission structure, light output from the light emitting layer 112 is output toward a cathode that is located above the light emitting layer 112, which is opposite to the bottom emission structure. In the third example, a so-called top gate structure in which the control gate 126 is disposed at the light emitting element side in the same manner as in the first example is adopted. In the configuration in this example, the electric potential of a channel is stably held by adopting a structure where the control gate 126 formed of indium tin oxide (ITO) is provided at the light emitting element side of the light detection element 120 and a desired voltage is applied to the channel region 121i of the thin film transistor that forms the light detection element 120. In addition, a reflective metal layer 105 is disposed on the entire glass substrate 100, and output light is emitted toward the cathode 113 side.

As described above, the electric potential of the control gate 126 is adjusted such that the thin film transistor that forms the light detection element 120 operates in the OFF region where a drain current is zero. Thus, it is possible to realize the light detection element 120 that is not affected by a voltage applied to the organic electroluminescent element 110 formed above the light detection element 120. Even in this case, it cannot be overemphasized that a distance between the control gate 126 and the polycrystalline silicon layer 121 and a voltage applied to the control gate 126 are important. In this example, the gate electrode 133 of the driving transistor and the control gate 126 of the light detection element are formed on the same layer and the control gate 126 and the channel region 121i are disposed to be much closer to each other such that a voltage control becomes easy. However, as already described in the first example, the gate electrode 133 of the driving transistor and the control gate 126 of the light detection element may also be formed on the same layer as the source and drain electrodes 125S and 125D. In this case, the wiring resistance in the source and drain electrodes 125S and 125D needs to be decreased to make a detected current large, and as a result, it becomes difficult to acquire sufficient transmittance as the control gate 126. Although the transmittance is not originally required even for the gate electrode 133 of the driving transistor, the transmittance is necessary in the case when the gate electrode 133 is formed on the same layer as the control gate of the light detection element. It is necessary to decide at which position the control gate 126 is to be disposed in consideration of wiring resistance and transmittance.

In the case when the top emission structure is adopted, about half of the light supplied for exposure is transmitted through the light detection element 120 and is then reflected from the control gate 126 which is a reflective metal layer. A polycrystalline silicon, which has high transparency but slightly low photocurrent generation capability, and an amorphous silicon, which has slightly low transparency but high photocurrent generation capability, may be arbitrarily selected for the light detection element 120. However, the light detection element 120 having a photoelectric conversion layer formed of an amorphous silicon, which has high photocurrent generation capability, may also be used.

In order to realize the top emission structure, it is necessary to form the transparent electrode 113 on an organic luminescent material. However, in order that the organic luminescent material is not damaged at the time of forming the transparent electrode, a cathode obtained by laminating a very thin metal layer (thin cathode), such as Al and Ag, and a transparent electrode, such as ITO, is used. Since the metal layer is very thin, transmittance is secured, electrons are injected into the light emitting layer very efficiently by a work function of the metal layer, and a cathode which has a low resistance and in which transmittance is secured is realized by a transparent electrode whose surface is thick enough. In addition, by forming a buffer layer with a metal oxide or a polymer material, damage at the time of forming a transparent electrode can also be reduced. In addition, a top emission structure where upper and lower sides of elements in the related art are simply changed, that is, the top emission structure where a cathode as a lower electrode and an anode as an upper electrode may also be used. In the case of the top emission structure, a manufacturing cost is increased since the number of manufacturing processes is increased compared with the bottom emission structure. However, in the case of the top emission structure, an optical head having satisfactory luminous efficiency can be realized.

### FOURTH EXAMPLE

In the fourth example of the invention, a structure of the light emitting device having a top emission and bottom gate structure, which was explained in the tenth to twelfth embodiments, will be described.

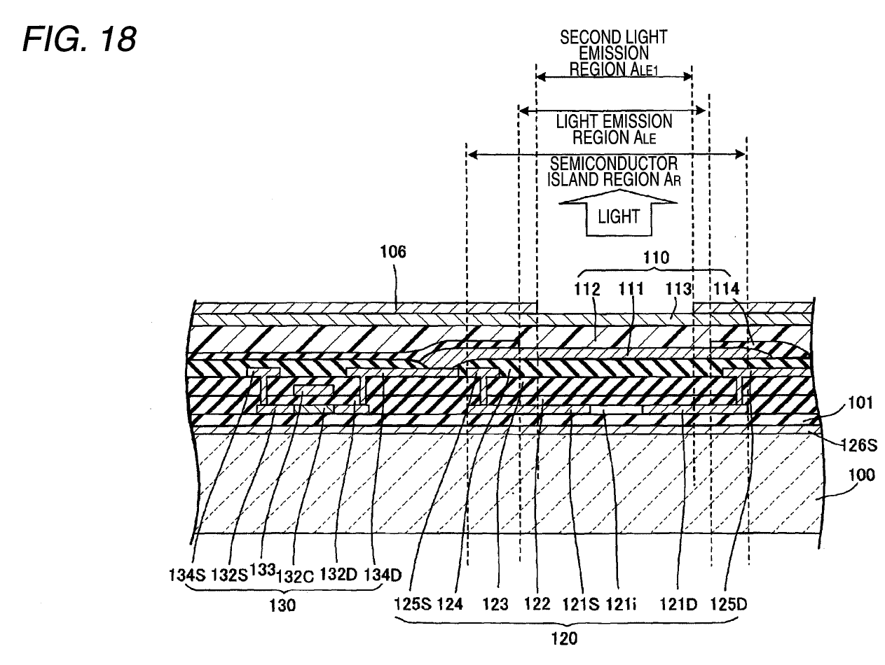

FIG. 18 is a cross-sectional view illustrating an optical head having a top emission structure. In this example, a so-called bottom gate structure where a control gate is disposed at the substrate side in the same manner as in the second example is adopted. In the fourth example, a structure where a control gate 126S formed of a reflective metal is provided on the entire surface of the glass substrate 100, output light is emitted toward the cathode side, and a desired voltage is applied to a gate electrode of the thin film transistor that forms the light detection element 120. As described above, the electric potential of the control gate 126s is adjusted such that the thin film transistor that forms the light detection element 120 operates in the OFF region where a drain current is zero. Thus, it is possible to realize the light detection element 120 that is not affected by a voltage applied to the organic electroluminescent element 110 formed above the light detection element 120. In this case, it cannot be overemphasized that a distance between the control gate 126 and the polycrystalline silicon layer 121 and a voltage applied to the control gate 126 are important.

In this configuration, a reflective layer and the control gate are formed on the same layer, and it is not necessary to form a thin layer used to form a separate control gate. Furthermore, since it is not necessary to perform patterning, it is possible to improve the characteristics without increasing the number of processes.

In addition, since the metal layer that forms the control gate 126S is formed on the entire surface of the glass substrate, unevenness of the surface resulting from a pattern of the control gate 126S can be prevented.

Hereinbefore, the configurations and the operations of the electroluminescent element 110 and the light detection element 120 that form the optical head have been described in detail. In the first to fourth examples, a case in which light emitting elements (electroluminescent elements) are provided in a row in the optical head has been described. However, a plurality of rows of light emitting elements may be provided to substantially increase the amount of emitted light.

In addition, as for the structures of the electroluminescent element 110 and the light detection element 120, the electroluminescent elements 110 and the light detection elements 120 may be arranged in a two-dimensional manner so as to be applied to a display device.

In addition, in the third and fourth examples of the invention, a light shielding layer 106 that is a thin film using a chromium may be formed on the cathode 113 of the electroluminescent element 110 facing a front surface of the glass substrate, and a second light emission region A_{LE1} is regulated by such openings. By forming the second light emission region A_{LE1} smaller than an opening of a silicon nitride layer serving as the pixel regulating unit 114 described in the first example, a step difference part of the light emitting layer resulting from the silicon nitride layer can be removed from the light emission region. As a result, it becomes possible to make the light emitting layer more uniform.

### FIFTH EXAMPLE

In a fifth example of the invention, an example of a light detection element 120S using a PIN diode will be described. In this example, a structure of a light emitting device having a bottom emission and top gate structure in the same manner as in the first example will be described.

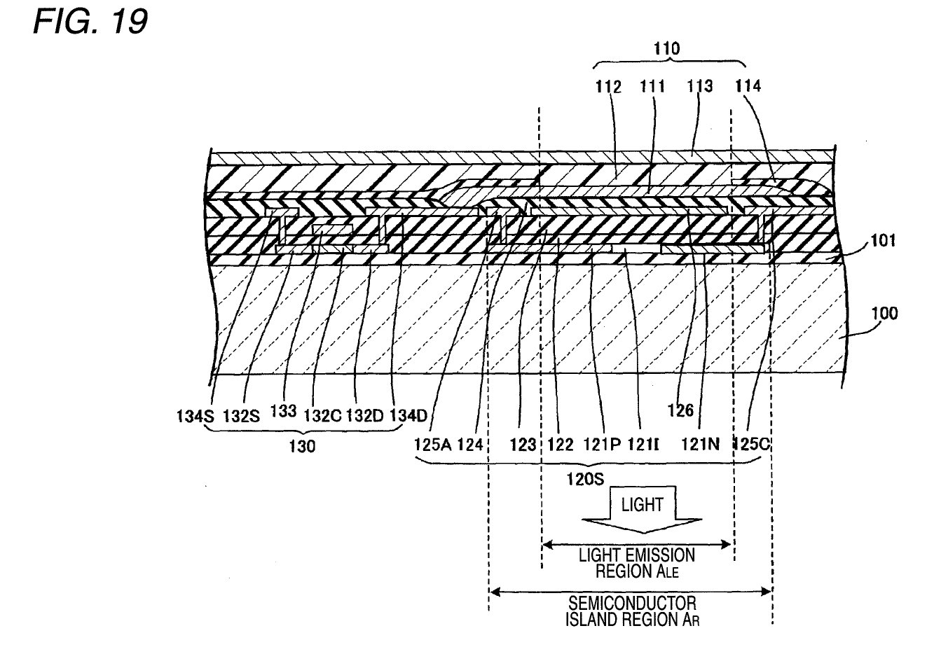

The light emitting device in the fifth example is different from the light emitting device in the first example of the invention, which is shown in FIG. 13, is that a PIN diode serving as the light detection element 120S is used instead of a thin film transistor serving as the light detection element 120. FIG. 19 is a cross-sectional view illustrating the configuration of a light emitting device, which is used in an optical head provided in an exposure unit of an image forming apparatus, in the fifth example. The light detection element 120S is formed in the same manner as the thin film transistor in the first example. However, the island region 121, which is formed of a polycrystalline silicon and forms an element region of the light detection element 120S, forms a P layer 121 P, an i layer 121i, and an N layer 121N by means of injection of impurities and the amount of light is detected by outputting a current between an anode electrode 125A and a cathode electrode 125C as a photoelectric conversion current.

A manufacturing process in this example is completely the same as that of the thin film transistor in the first example except for only a process of injecting impurities, and accordingly, a detailed explanation will be omitted herein.

Even in this example, in an island region 121 of the light detection element 120S obtained as a result of forming a step difference, an outer edge of an element region A_{R} is formed to be an outside of the light emission region A_{LE} of the electroluminescent element. In addition, there is no step difference in a region corresponding to a light detection region of the electroluminescent element, and a base of the light emitting layer forms a flat surface. Accordingly, in a light emission region which is to be an effective region of an optical head, a light emitting layer of the optical head is uniformly formed.

Thus, the light detection element of the invention is not limited to a thin film transistor but may be applied to various photoelectric conversion elements, such as a junction transistor and a photodiode.

### Thirteenth Embodiment

For example, JP-A-2000-357815 discloses the configuration in which a light emitting element, such as an electroluminescent element, and a light detection element are combined.

In a technique disclosed in JP-A-2000-357815, in order to simplify the configuration of a photo-sensing element including a light emitting element and a light detection element, the light detection element that can be made thin is disposed in parallel with a light emitting layer of an organic electroluminescent element, reflected light occurring due to a multi-layered thin layer formed below the light emitting layer is detected in the light detection element.

In the technique disclosed in JP-A-2000-357815, a light detection element and the light emitting part of the electroluminescent element are provided on the same plane (on the same layer), and light emitted from the light emitting part is introduced into the light detection element by reflection due to the multi-layered thin layer. As a result, since crosstalk occurring due to light output from adjacent light emitting elements increases, it has been difficult to detect the amount of light emitted from a plurality of light emitting elements at the same time.

In recent years, however, as the resolution of an image forming apparatus increases and an element pitch of a light emitting element decreases, an issue related to the cross talk becomes important. That is, it is important to detect the amount of light without being affected by light emitted from adjacent electroluminescent elements. It is different to solve the problem described above using the technique disclosed in JP-A-2000-357815.

In the thirteenth embodiment, it is an object to provide a light emitting device capable of detecting the amount of light with high accuracy by improving the detection accuracy of a light amount sensor (light detection element) and capable of emitting a desired amount of light. Further, it is another object to reduce the cross talk. Furthermore, it is still another object to provide a light emitting device whose amount of emitted light is stable.

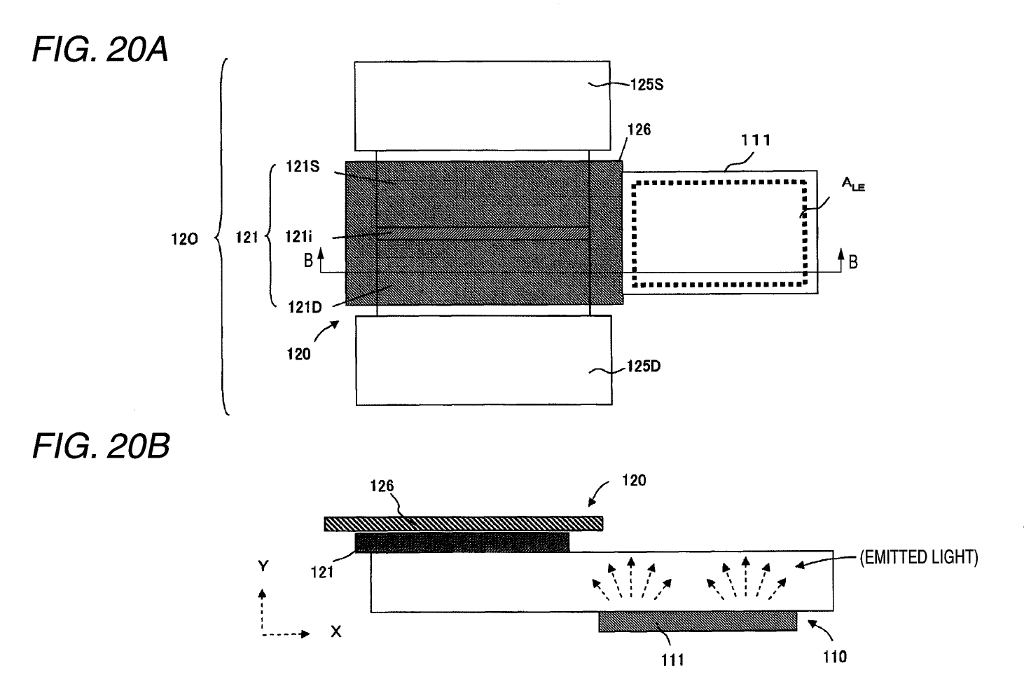

In the thirteenth embodiment, as schematically shown in FIGS. 20A and 20B, the electroluminescent element 110 is provided to be shifted from the light detection element 120 by a predetermined distance (in X and Y directions) such that the light detection element 120 is positioned outside the light emission region A_{LE} of the electroluminescent element 110. The amount to be shifted is determined by simulation and only direct light or reflected light can be detected as much as the desired amount of light.

That is, the light detection element 120 and the light emitting element 110 are laminated on a transmissive substrate (not shown), and light is extracted from the transmissive substrate side. The light detection element 120 is configured to include: the source and drain regions 121S and 121D that are n-type impurity regions formed by injecting impurity ions into the island region 121 formed of polycrystalline silicon; the channel region 121i that is a non-doped layer located between the source and drain regions 121S and 121 D and has two layers; and the control gate 126 that is formed on a surface of the island region with a gate insulating layer (not shown; corresponds to the first insulating layer 122 and the second insulating layer 123 formed of a silicon oxide layer in FIG. 13) formed of a silicon oxide layer interposed therebetween. The control gate 126 is formed of ITO (indium tin oxide) or doped polycrystalline silicon. In addition, the control gate 126 is formed of a metal, such as Cr, Mo, or Al in the case when the transmittance is not required. The control gate 126 is formed to have a width enough to cover at least the channel region 121i over the entire channel width of the light detection element 120.

FIG. 20B is a cross-sectional view taken along the line XXB-XXB of FIG. 20A.

The source and drain electrodes 125S and 125D formed of polycrystalline silicon are formed above the source and drain regions 121S and 121D, respectively, and the control gate 126 and the source and drain electrodes 125S and 125D are disposed on the same side with respect to the channel region 121i, thereby forming a so-called coplanar structure.

Since the light emitting element 110 has already been described above, a detailed explanation thereof will be omitted. The light emitting element 110 is formed by laminating the anode 111 serving as a first electrode, which is made of ITO (indium tin oxide), the pixel regulating unit 114 (an insulating layer that specifies a light emission region), the light emitting layer 112, and the cathode 113 serving as a second electrode in this order. Although the size of the anode 111 is shown in a square shape in FIGS. 20A and 20B, the light emission region A_{LE} where actual light emission is performed corresponds to the size of an opening (a part drawn in a dotted line inside the anode 111) of the pixel regulating unit 114 of the light emitting element 110.

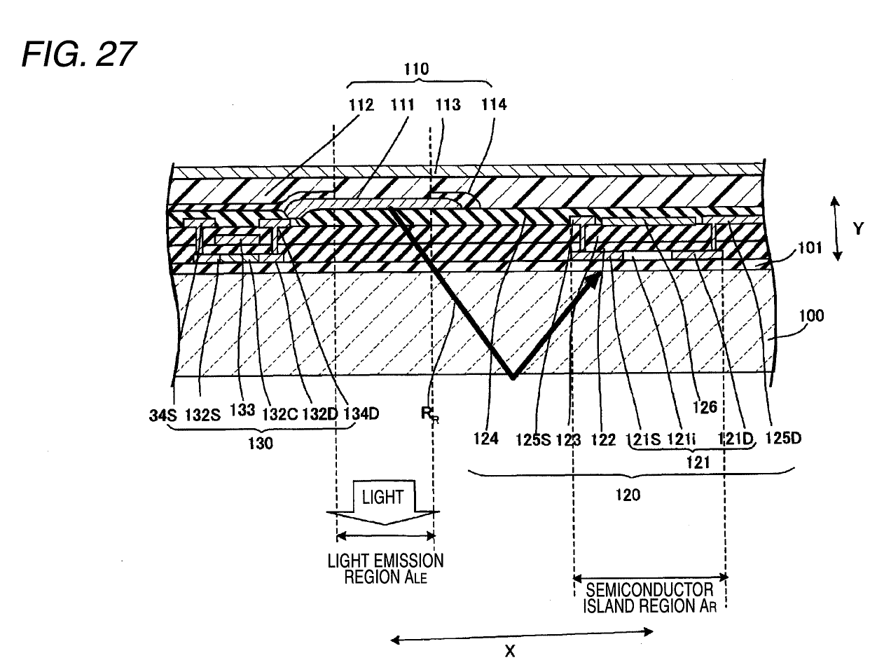

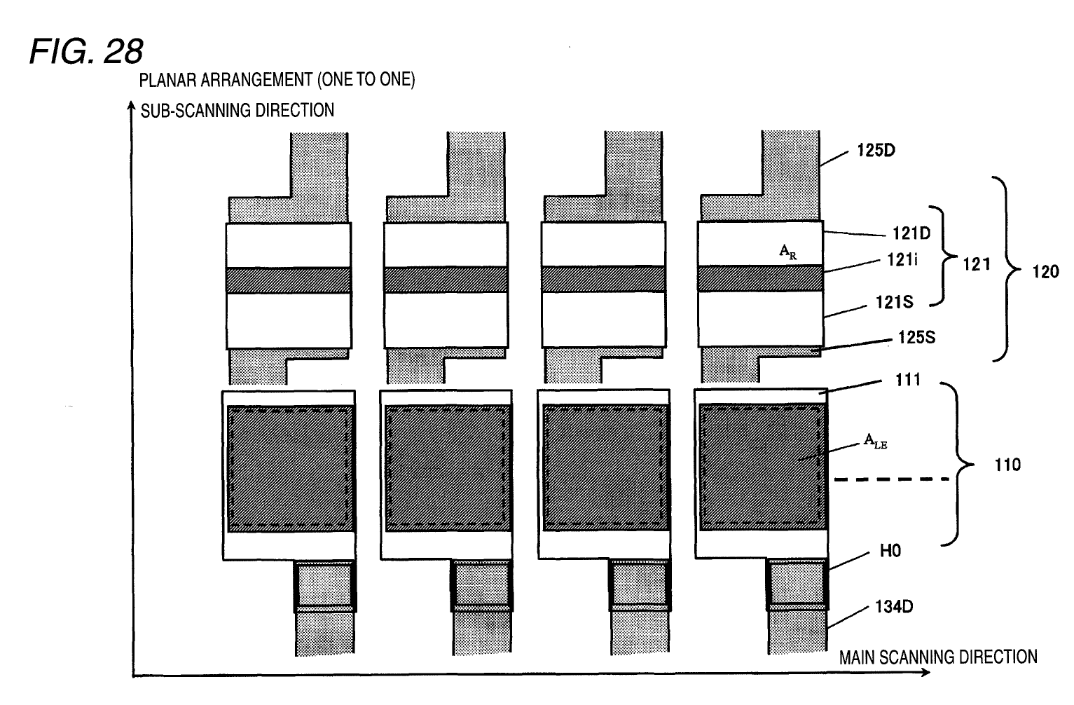

According to the configuration described above, unevenness resulting from the light detection element 120 is not formed inside a light emission region (luminous region) of the light emitting element 110 and in the periphery thereof by forming the light detection element 120 at the position shifted from directly below the electroluminescent element 110. As a result, it is advantageous in that uniformity of light emission in the light emitting layer 112 (refer to FIG. 27) is easily improved (here, in the case of a light emitting device in a sixth example (refer to FIGS. 27 and 28) which will be described later, the electrode arrangement of the light detection element 120 with respect to the light emitting element 110 is different from that in this configuration by 90° but others are the same.

In addition, since light diffused from the light emitting element 110 is incident on the light detection element 120, the amount of light incident on the light detection element 120 is small compared with a case in which the light detection element 120 is configured to overlap directly below the light emitting element 110. For this reason, since an effect of high-brightness light exposure on temporal deterioration of the light detection element 120 can be reduced, the configuration is important particularly in a high-brightness device, such as an optical head. However, since the amount of light incident on the light detection element 120 is small, it is preferable to use a light detection element 120 having high sensitivity, such as a PIN diode, depending on the amount of light incident on the light detection element 120. Moreover, in the case when the light detection element 120 is formed at the position shifted from directly below the anode 111 of the light emitting element 110, restriction on an area of the light detection element 120 is decreased. Accordingly, in this case, since it is possible to increase the amount of light incident on the light detection element 120 by forming the light detection element 120 having a large area, it is preferable to use a light detection element having a large area.

Further, according to this configuration described above, the light detection element 120 is formed on a different layer and at the position shifted from directly below the anode 111 of the light emitting element 110, such that light from the inclined direction is detected. Since the light detection element 120 is not formed directly below the light emitting element 110, an effect of the electric potential of the light emitting element 110 (here, the anode 111 of the light emitting element 110) with respect to the electric potential of the light detection element 120 is small. Accordingly, the control gate 126 may not be provided. However, if the control gate 126 is not formed, the light detection element 120 is affected by the electric potential of the light emitting element 110 depending on the arrangement of the light emitting element 110 and the light detection element 120, and the light detection sensitivity of the light detection element 120 is changed by the electric potential applied to the light emitting element 110. As a result, stable light detect may be difficult. Particularly in the case of performing light detection using a minute current, the effect is noticeable. Furthermore, the electric potential of the light detection element 120 may be easily affected by an electric potential which is unstable, such as static electricity that may be generated on a surface of a glass substrate (not shown), such that stable light detection may not be performed. Particularly in the case when the light detection element 120 is formed of a thin film transistor shown in the present embodiment, a polarity of a channel that forms the thin film transistor and a polarity of the electric potential applied to the light emitting element 110 may be affected by the electric potential of the light emitting element 110 even in this configuration.

Thus, depending on the arrangement of the light emitting element 110 and the light detection element 120, sensor characteristics may become unstable due to variation in the electric potential the channel region 121i of the light detection element 120. Accordingly, like the light emitting device according to the present embodiment, it is preferable to form the control gate 126 at least on the channel region 121i of the light detection element 120.

In the case of detecting the amount of light in a device such as an optical head in which the plurality of light emitting elements 110 and the plurality of light detection elements 120 are arranged, there is a case in which the amount of light emitted from adjacent light emitting elements and incident on the light detection element 120 is not negligible as compared with the amount of light, which is to be actually detected, emitted from the light emitting element 110 and incident on the light detection element 120 when trying to detect the adjacent light emitting elements 110 at the same time. In such a case, since a detected current deviates from the amount of light, which is to be actually detected, emitted from the light emitting element 110, light detection which is highly precise is not possible.

Accordingly, in the case of performing light detection in the configuration where the plurality of light emitting elements 110 and the plurality of light detection elements 120 are arranged, the light detection which is highly precise is realized by simultaneously performing light detection between the light emitting element 110 and another light emitting element 110, which is apart from the light emitting element 110 so that the amount of light emitted from the light emitting element 110 can be sufficiently negligible, and by sequentially setting different time so as to perform the detection without performing the light detection at least in the adjacent light emitting element 110. Alternatively, in the case when the light detection element 120 is formed at the position shifted from directly below the anode 111 of the light emitting element 110, the amount of light that is directly incident on the light detection element 120 from the light emitting element 110 is decreased as a distance between the light emitting element 110 and the light detection element 120 is increased. Accordingly, in this case, the light detection may be performed using light, which is reflected from an interface between a glass substrate (not shown) and an air, of light radiating from the light emitting element 110.

In the configuration described above, the amount of reflected light is increased at an angle at which total reflection occurs in the interface between a glass substrate (not shown) and an air. Accordingly, it is preferable to form the light detection element 120 at the position where the totally reflected light reaches. In the case of light detection using reflected light, since the reflected light propagates while diffusing, light that reaches the light detection element 120 is distributed over a wide range compared with a case of detecting direct light. For this reason, it is preferable to form a light detection element having a large area as compared with the light detection element 120 that directly detects light. By using such light detection element 120 having a large area, it becomes possible to perform light detection with one light detection element 120 corresponding to the plurality of light emitting elements 110.

Hereinbefore, the light emitting device in which the light detection elements 120 are disposed to be shifted with respect to the light emitting element 110 has been described. Here, in order to detect light on a desired path with high accuracy, it is necessary to adjust the relative positions between the light emitting element 110 and the light detection element 120 and a surrounding optical environment. Therefore, in the thirteenth embodiment, a method of determining the optimal amount to be shifted is used. That is, the relative positions between the light emitting element 110 and the light detection element 120 are determined by simulation. Hereinafter, this simulation method will be described.

First, the illuminance corresponding to the position of a sensor surface of the light detection element 120 when the electroluminescent element 110 has been caused to emit light with the predetermined amount of light is measured.

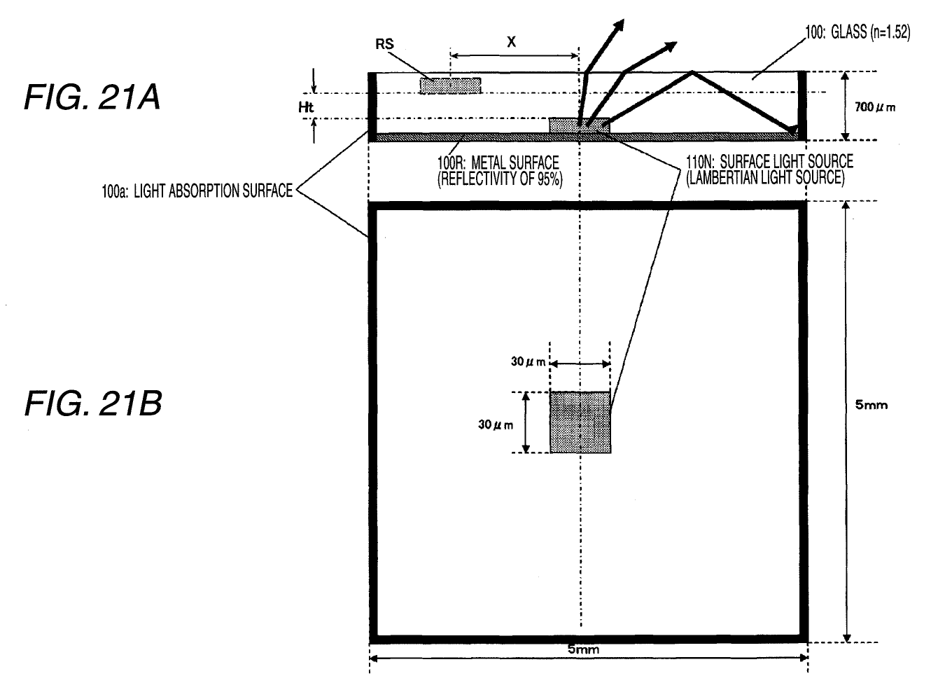

In the thirteenth embodiment, as shown in FIGS. 21A and 21B, a simulation model in which a luminous body 110N (light emitting element) having sides of 30 μm and light emitting brightness of 10000 cd/cm² is formed on a main surface of the glass substrate 100 having width and depth of 5 mm, a thickness of 0.7 mm, and a refractive index n of 1.52 is considered. In addition, it is assumed that the luminous body 110N is provided inside the glass substrate 100 in order to simplify a model. It is assumed that a side surface of the glass substrate 100 is a light absorption surface 100a and a lower surface of the glass substrate 100 is a metal surface 100R (reflectivity: 50%).

FIG. 21A is a view illustrating a state in which the luminous body 110N is disposed on a lower main surface of the glass substrate 100, and FIG. 21B is a top view illustrating the luminous body and the glass substrate 100.

In this simulation, it is assumed that light emitted from the luminous body 110N is received in a light receiving body RS having a size of 30 μm×30 μm. In this state, the illuminance of light received in the light receiving body RS was obtained by calculation by causing the light receiving body RS to be spaced apart from the luminous body 110N by a distance Ht upward from the luminous body 110N and by moving the light receiving body RS in the X direction shown in the drawing.

The distance Ht was set to 1.0 μm in consideration of an actual distance between the light emitting element 110 and the light detection element 120 (for example, refer to FIG. 27), which will be described later. Furthermore, the thickness of the luminous body 110N was set to 0.1 μm assuming that a corresponding device is an organic electroluminescent element.

Using such simulation model described above, an output of the luminous body was adjusted such that a value of power measured becomes 340 mW at the time of emission of 10000 cd/cm².

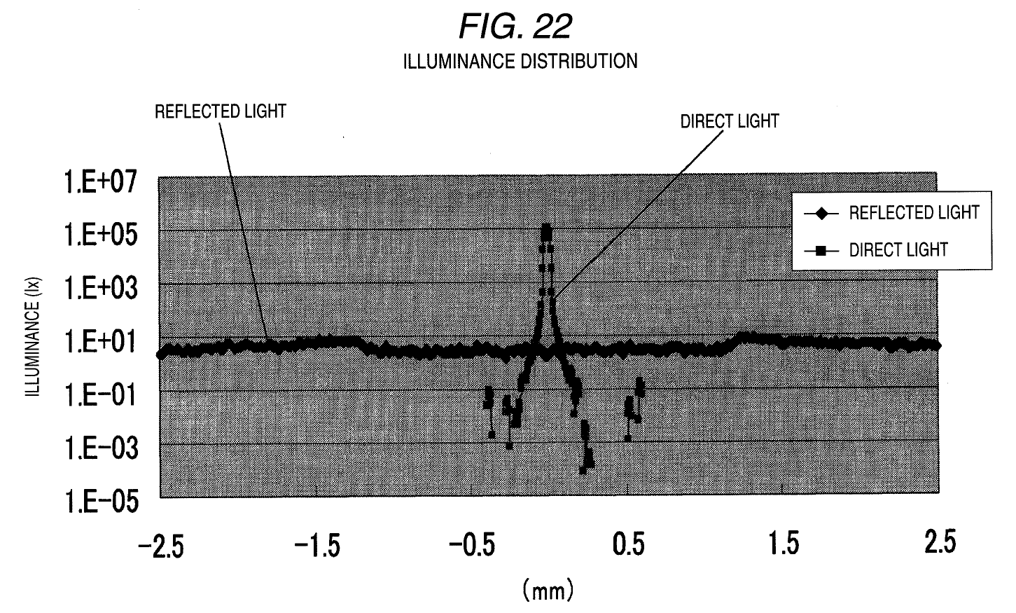

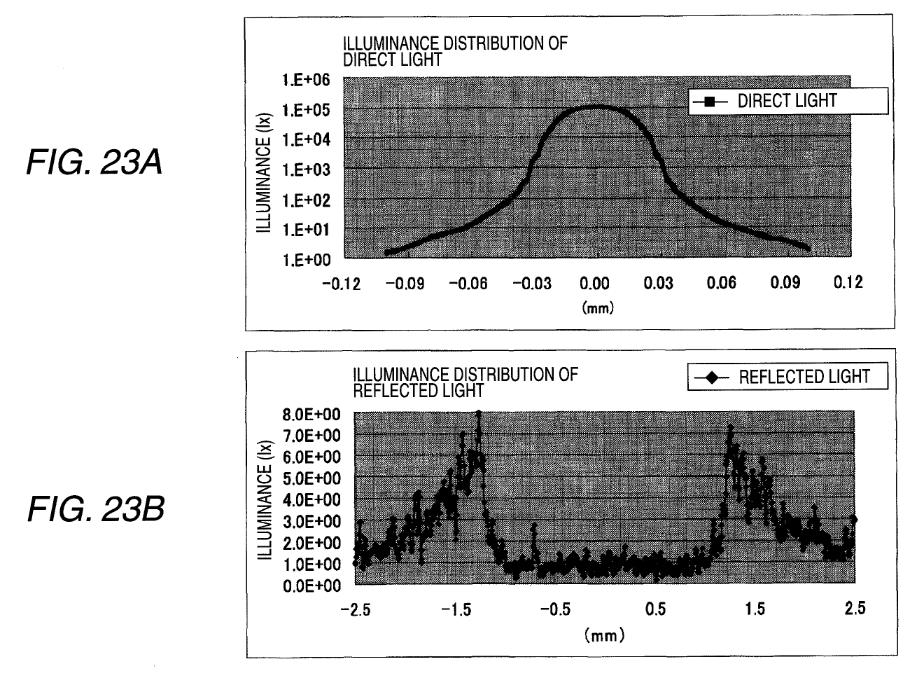

Simulation results of direct light and reflected light at this time are shown in FIGS. 22, 23A, and 23B. FIG. 23A is an enlarged view illustrating direct light shown in FIG. 22, and FIG. 23B is an enlarged view illustrating reflected light shown in FIG. 22 (here, scales in FIGS. 23A and 23B are not equal).

As is apparent from these drawings, it could be seen that the illuminance increases in a range of about 0.03 mm from a center of the luminous body 110N in the case of illuminance distribution of direct light, and illuminance distribution of reflected light is almost constant but the illuminance decreases in a range of about 1.2 mm from the center of the luminous body 110N.

This result shows that higher measurement accuracy can be obtained by measuring the direct light in a region where the illuminance distribution of reflected light is low.

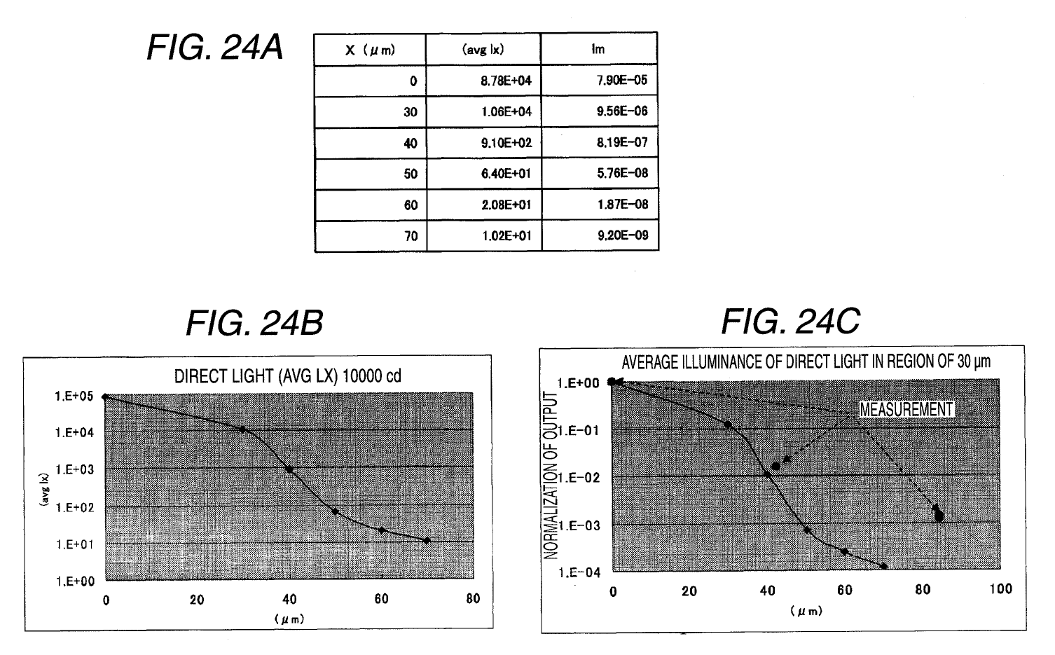

Using the simulation model described above, the relationship between the light receiving body RS in a region, which is distant by X (μm) from immediately above the luminous body 110N, and the amount of received light was calculated. Simulation results are shown in FIGS. 24A to 24C.

In FIG. 24C, actual measurement values measured in a state in which a light emitting element is actually made are also plotted.

As a result, in the case of detecting direct light, it can be understood that a highly precise detection output is obtained by taking a measurement in a range of X=0 to 50 μm.

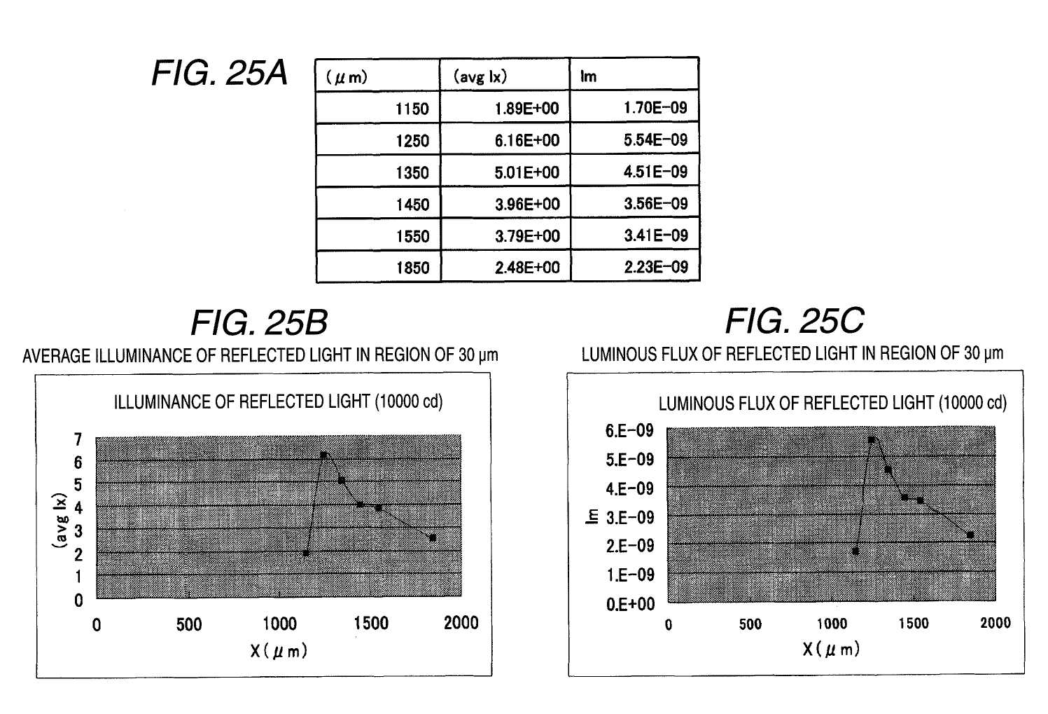

Furthermore, using the simulation model described above, the relationship between the light receiving body RS in a position, which is distant by X (μm) from the luminous body 110N, and the amount of received light was calculated. At the time of calculation, a luminous flux and an average illuminance on a surface of the light receiving body RS were measured. Simulation results are shown in FIGS. 25A to 25C.

As a result, in the case of detecting reflected light, it can be understood that a highly precise detection output is obtained by taking a measurement in a range of X=1250 to 1550 μm.

Next, a method of determining the position of a light detection element by performing simulation using such a simulation model will be described.

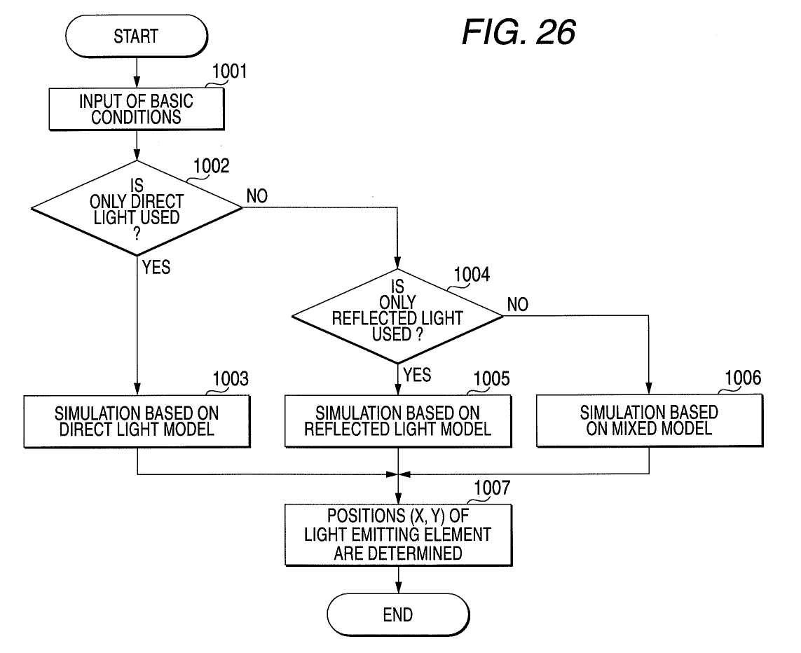

A flow chart is shown in FIG. 26.

First, basal conditions, such as the thickness of a glass substrate, a refractive index, and surrounding conditions, are input (step 1001). Then, it is determined whether or not to use only direct light (step 1002). If it is determined ‘Yes’ in step 1002, simulation is performed using the direct light simulation model shown in FIGS. 21A and 21B (step 1003), and a desired position is determined (step 1007). If it is determined ‘No’ in step 1002, it is determined whether or not to use only reflected light (step 1004). If it is determined ‘Yes’ in step 1004, simulation is performed using the reflected light simulation model shown in FIGS. 21A and 21B (step 1005), and a desired position is determined (step 1007). On the other hand, if it is determined ‘No’ in step 1004, simulation is performed using the direct light simulation model shown in FIGS. 21A and 21B and the reflected light simulation model shown in FIGS. 21A and 21B (step 1005), and a desired position is determined (step 1007).

Thus, it is possible to determine the position of a light detection element such that the desired amount of light can be detected.

Hereinafter, six to eleventh examples will be described in detail on the basis of the simulation explained in the thirteenth embodiment.

### SIXTH EXAMPLE

In the sixth example, a bottom emission type light emitting device is adopted as shown in FIG. 27. The light detection element 120 and the driving transistor 130 are formed on the glass substrate 100, and the electroluminescent element 110 serving as a light emitting element is provided on the light detection element 120 and the driving transistor 130. A thin film transistor serving as the light detection element 120, which is shifted by a predetermined distance in the horizontal direction X and vertical direction Y from the electroluminescent element 110, is provided. The distances X and Y are determined from the simulation result described in the thirteenth embodiment. Although a thin film transistor was herein used as the light detection element 120, other thin film sensors including diodes, such as a PIN diode and a PN diode.

FIG. 27 is a cross-sectional view illustrating the configuration of a light emitting device, which is used in an optical head provided in an exposure unit of an image forming apparatus, and FIG. 28 is a top view illustrating main parts of the light emitting device. In the sixth example, the electroluminescent element 110 serving as a light source is formed at a position (position distant by X in the horizontal direction and Y in the vertical direction) upwardly inclined from the light detection element 120 with the control gate 126 interposed therebetween, such that light emitted from the electroluminescent element 110 serving as the light source is reflected on an interface between the glass substrate 100 and an air layer and is then incident, as a reflected light RR, on the channel region 121i of the light detection element 120 from a lower side (glass substrate 100 side). As the configuration of the light emitting device, the light detection element 120 and the driving transistor 130 are provided on the glass substrate 100, and the electroluminescent element 110 serving as a light source is laminated on the light detection element 120 and the driving transistor 130. In addition, the thin film transistor that forms the light detection element 120 is configured to include the control gate 126 formed of a polycrystalline silicon layer. In addition, the electric potential of the channel region 121i is controlled by the control gate 126, and the thin film transistor that forms the light detection element 120 is not affected by the electric potential of the anode 111 of the electroluminescent element 110.

As shown in FIG. 28, the light emitting device is formed such that the electroluminescent element 110 is laminated on a thin film transistor (TFT), which forms the light detection element 120 formed on the glass substrate 100, and the island region 121 that is formed of a polycrystalline silicon and forms an element region of the light detection element 121 is completely separated from the light emission region A_{LE} of the electroluminescent element so as to be positioned outside the light emission region A_{LE} of the light emitting element 110. In the light emitting device, the control gate 126 is disposed to reliably cover the channel region 121i, such that the electric potential of the channel region 121i is reliably controlled.

Further, in the sixth example, as shown in FIG. 27, an interface formed in a boundary between the glass substrate 100 and the air is formed as an interface from which light emitted from the electroluminescent element 110 is reflected, and the distances in the X and Y directions are determined such that the light emitted from the electroluminescent element 110 is reflected and is incident on the light detection element 120. Typically, the first insulating layer 122, the second insulating layer 123, the protective layer 124, and the like are formed between a surface formed with the light emitting layer 112 of the electroluminescent element 110 and a surface formed with the light detection element 120. The thicknesses of the first insulating layer 122, the second insulating layer 123, and the protective layer 124 are all in a range of tens of nanometer to hundreds of nanometer. Accordingly, even if the position of the electroluminescent element 110 and the position of the light detection element 120 are adjusted by controlling the thicknesses, the degree of freedom is small. For this reason, basically, it is preferable to determine the thickness of the protective layer 124 and the like and then determine the X-direction position for forming the light detection element 120.

Here, a design is made such that total reflection is realized on the interface described above. However, the distance ‘X’ may be determined such that light emitted from the electroluminescent element 110 is reflected from a reflective surface and is then incident on the light detection element 120. Alternatively, the distance may be determined such that the light emitted from the electroluminescent element 110 is reflected from an interface, which is formed in a boundary between the glass substrate 100 and the air, by the Fresnel reflection and is then incident on the light detection element 120.

Alternatively, the distance may be determined such that the light detection element 120 is formed at the position on which light, which is emitted from the light emission region A_{LE} of the electroluminescent element 110 and is reflected according to a critical angle on a total reflection surface, is incident. In this case, even if the electroluminescent element 110 and the light detection element 120 are far from each other, high-intensity light occurring due to total reflection is incident on the light detection element 120. In addition, it is preferable to dispose a light detection element such that light emitted in the normal line direction from a central point of a luminous region reaches the middle of a channel region of the light detection element through reflection based on the critical angle.

Alternatively, the distance may be determined such that the light detection element 120 is formed at the position on which light, which is emitted from the light emission region A_{LE} of the electroluminescent element 110 and is reflected a plural number of times according to the critical angle on a total reflection surface, is incident.

In the case of using reflected light, other structures should not be provided on the interface between the glass substrate 100 and an air layer. For example, although the light emission region A_{LE} may also be regulated by providing a light shielding part (that is, aperture) on a surface opposite a surface on which the electroluminescent element 110 is formed, the light emission region A_{LE} should not be provided at the position where the total reflection and the like are required, since such aperture has generally a light absorption property. Moreover, in the sixth example, the glass substrate 100 is designed to be provided in a housing (not shown) so that a part requiring the total reflection state is not in contact with the housing when forming an exposure apparatus.

As is apparent from FIGS. 27 and 28, the island region A_{R} of the light detection element 120 that forms a step difference in a laminated structure, that is, the element region 121 is formed to be located outside the light emission region A_{LE} of the electroluminescent element 110. In such a manner, the step difference does not occur in a region equivalent to the light emission region A_{LE} of the electroluminescent element 110 and a base of the light emitting layer 112 becomes a flat surface. Accordingly, in the light emission region A_{LE} that becomes an effective region at the time of light illumination of an optical head, the thickness of the light emitting layer 112 is formed uniformly.

That is, as shown in FIG. 27, in the light emitting device in the sixth example, the light detection element 120 having the control gate 126 and the electroluminescent element 110 are sequentially laminated on the glass substrate 100 where the base coat layer 101 for planarization is formed on a surface, and a thin film transistor serving as the switching transistor 130 for driving the electroluminescent element 110 while correcting a driving current or a driving time in accordance with an output of the light detection element 120 and a driving circuit, which serves as a chip IC, connected to the driving transistor 130 are mounted. In addition, in the light detection element 120, the source region 121S and the drain region 121D are formed by doping the island region A_{R}, which is formed of a polycrystalline silicon layer formed on a surface of the base coat layer 101, in a desired concentration under a condition in which the island region A_{R} is spaced apart from the channel region 121i formed of a strip-shaped i layer. The light detection element 120 is configured to include the source and drain electrodes 125S and 125D formed of a polycrystalline silicon layer that is formed to penetrate the first insulating layer 122 and the second insulating layer 123, which are silicon oxide layers formed on the source and drain regions 121S and 121D, using a through hole and the control gate 126 formed of ITO. Furthermore, the electroluminescent element 110 is formed on the layer obtained as the above result with a silicon nitride layer serving as the protective layer 124 interposed therebetween. Specifically, an ITO (indium tin oxide) 111, which is to be the anode 111 serving as a first electrode, the pixel regulating unit 114, the light emitting layer 112, and the cathode 113 serving as a second electrode are laminated in this order. Here, the insulating layer (pixel regulating unit) 114 for defining the light emission region A_{LE} is formed on the anode 111.

If the configuration of the light emitting device in the sixth example is simply expressed, it can be said that the entire light detection element 120 is laminated outside the light emission region A_{LE} of the electroluminescent element 110.

On the other hand, the driving transistor 130 is formed in the same manufacturing process as each of the layers that form the light detection element 120. That is, source and drain regions 132S and 132D are formed with a channel region 131C interposed therebetween in the same process as a semiconductor island region of the light detection element 120, and source and drain electrodes 134S and 134D being in contact therewith are laminated. The source and drain electrodes 134S and 134D and a gate electrode 133 form a thin film transistor serving as the driving transistor 130.

Each of the layers is formed using typical semiconductor processes, such as formation of a semiconductor thin film using a CVD method, a sputtering method, and a vacuum deposition method, polycrystallization using annealing, patterning using photolithography, etching, injection of impurity ions, and formation of an insulating layer and a metallic layer.

Materials described in the first example may be used as materials of the glass substrate 100 and a substitute thereof.

However, in the case of the sixth example, simulation is performed on the basis of a refractive index of each material, such that a distance between the electroluminescent element 110 and the light detection element 120 is optimally maintained.

Processes of forming the base coat layer 101 formed on the glass substrate 100 and the semiconductor island region A_{R} (element region 121 formed of polycrystalline silicon or amorphous silicon) on the base coat layer 101, the configuration of the control gate 126, an organic luminescent material, a hole transport material, an electron transport material, the cathode 113, and the like are similar to those in the first example, and accordingly, an explanation thereof will be omitted.

As shown in FIG. 28, an optical head in the sixth example is formed by disposing the plurality of electroluminescent elements 110 in the main scanning direction (direction of a row of elements), and one light detection element 120 is disposed to correspond to one luminous region (light emission region A_{LE}). By adopting such structure, the amount of emitted light of each organic electroluminescent element 110 can be independently measured by the light detection element 120. That is, it becomes possible to measure the amount of light of the plurality of organic electroluminescent elements 110 at the same time. As a result, it is possible to greatly reduce the measuring time.

In FIG. 28, the relationship among the light detection element 120, the drain electrode 125D serving as an output electrode of a light detection element, the source electrode 125S serving as a ground electrode of a light detection element, the light emission region A_{LE}, the semiconductor island region A_{R} (element region 121), the ITO (indium tin oxide) 111 which is to be an anode of the light emitting layer 112, the contact hole HD, and the drain electrode 134D is shown. The light detection element 120 is connected to the drain electrode 125D serving as the output electrode of the light detection element and the source electrode 125S serving as the ground electrode of the light detection element. The drain electrode 125D serving as the output electrode of the light detection element is an electrode serving to transmit an electrical signal, which is output from the light detection element 120 for the purpose of correction of light, to a correction circuit (not shown). A feedback signal generated by the correction circuit is determined on the basis of the electrical signal, and processing required for correction of light is performed on the basis of the feedback signal. In the sixth example, the amount of emitted light of each electroluminescent element 110 is corrected on the basis of the feedback signal, and a value of a current for driving each electroluminescent element 110 is controlled by a driver circuit (not shown). As described above, in the sixth example, the amount of emitted light is controlled on the basis of an output of the light detection element 120. However, it may be possible to perform a so-called PWM control in which a driving time of each electroluminescent element 110 is controlled on the basis of the feedback signal.

The source electrode 125S serving as a ground electrode of a light detection element is an electrode used to ground the light detection element 120. The ITO (indium tin oxide) 111, which is an anode of the electroluminescent element 110 serving as a light emitting element, is connected to the drain electrode 134D of the driving transistor 130, and the electroluminescent element 110 is controlled by the driving transistor 130 through the drain electrode 134D.

As shown in FIGS. 27 and 28, in the optical head in the sixth example, the light detection elements 120 that are formed in the island shape using polycrystalline silicon (polysilicon) are disposed in rows in the main scanning direction. In addition, in each electroluminescent element 110, the channel region 121i of the light detection element 120 is covered with the control gate 126, such that variation in the electric potential due to change in the electric potential of the anode 111 does not occur in the channel region 121i. In addition, the light detection element 120 having the semiconductor island region A_{R} (element region 121) formed of island-shaped polycrystalline silicon is disposed below the light emitting layer 112, in which the light emission region A_{LE} is restricted by a silicon nitride layer serving as the pixel regulating unit 114, so as to be spaced apart from the light emission region A_{LE}. By forming the light emission region A_{LE} and the element region A_{R} (island-shaped part of polycrystalline silicon formed in the island shape) of the light detection element 120 so as to be spaced apart from each other, a change in local layer thickness of the light emitting layer 112 can be suppressed. Accordingly, it is possible to suppress variation in a current flowing through the light emitting layer 112. As a result, it becomes possible to manufacture an optical head in which uniform distribution of emitted light and an improvement in life time are realized.

Furthermore, since the element region 121 (semiconductor island region A_{R}) of the light detection element 120, which is mounted in the optical head in the first example and is formed in the island shape, is larger than a luminous region, that is, the light emission region A_{LE}, it is possible to efficiently convert output light from a light emitting layer into an electrical signal used for correction of light.

Processes for detecting the amount of light by processing the electrical signal obtained as described above have already explained using FIG. 15, and accordingly, an explanation thereof will be omitted.

In the above description, DC driving has been applied to the organic electroluminescent element. However, an AC voltage, an AC current, or a pulse wave may be used to drive the organic electroluminescent element.

### SEVENTH EXAMPLE

Although there was no overlapping region in the sixth example of the invention since the light emitting element 110 and the light detection element 120 are largely shifted from each other in the horizontal direction, a seventh example is characterized in that the light emitting element 110 and the light detection element 120 are disposed closely such that some parts thereof overlap each other, and direct light can also be received in addition to light that is emitted from the light emitting element 110 and is reflected from a lower surface of the glass substrate 100.

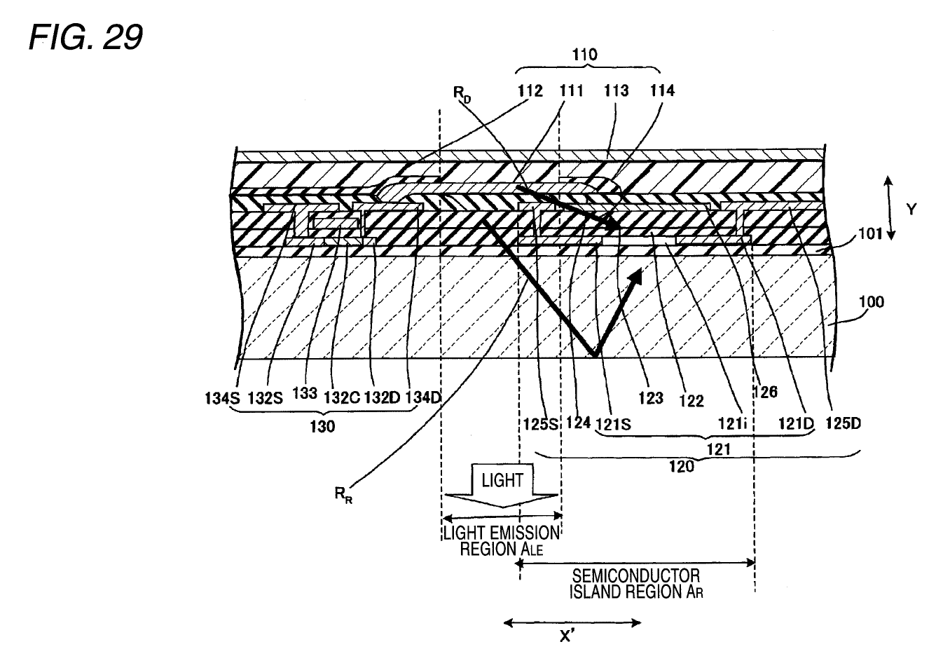

That is, in the light emitting device described above, as shown in FIG. 29, the electroluminescent element 110 serving as a light source is formed at a position (position distant by X′ in the horizontal direction and Y in the vertical direction) upwardly inclined from the light detection element 120 with the control gate 126 interposed therebetween, such that light emitted from the electroluminescent element 110 serving as the light source is incident, as direct light RD, on the channel layer 121i of a thin film transistor that forms the light detection element 120 and reflected light RR reflected from an interface between the glass substrate 100 and an air layer is incident on the channel layer 121i from the lower side. The distances X′ and Y are determined from the simulation result described in the thirteenth embodiment. The configuration of the light emitting device is the same as that in the sixth example except that only relative positions of the light emitting element 110 and the light detection element 120 are different.

Since the light detection element 120 is configured to receive direct light, a material that does not allow light to be transmitted therethrough cannot be used for the control gate 126. Accordingly, a transparent material should be used for the control gate 126 (gate electrode), the channel region 121i, and the source and drain regions 121S and 121D of the light detection element 120 in order that light output from the light emitting layer 112 is not blocked. As the transparent material of the light detection element 120, it is desirable to select polycrystalline silicon, for example.

If the configuration of the light emitting device in the seventh example is simply expressed, it can be said that a part of the light detection element 120 is laminated outside the light emission region A_{LE} of the electroluminescent element 110.

The other configurations are the same as that in the sixth example.

Furthermore, in the seventh embodiment, as shown in FIG. 29, light emitted from the electroluminescent element 110 is received as the direct light RD, an interface formed in a boundary between the glass substrate 100 and the air is formed as an interface from which light emitted from the electroluminescent element 110 is reflected, and a distance is determined such that the light emitted from the electroluminescent element 110 is reflected from the interface by the Fresnel reflection and is then incident on the light detection element 120.

Here, a design is made such that the total reflection is not realized but the Fresnel reflection is realized. However, the distance may be determined such that a reflective surface is formed on the interface and light emitted from the electroluminescent element 110 is reflected from the reflective surface and is then incident on the light detection element.

Furthermore, in the case when the configuration in the seventh example is adopted, a structure (for example, the source region 121S and the source electrode 125S) that forms the light detection element 120 is included in a range of the light emission region A_{LE}. In this case, the thickness of the light emitting layer 112 formed on the light detection element 120 may be not uniform in a region of the structure due to an influence of a step difference on the structure. As a result, there is a possibility that distribution (distribution within a surface) of the amount of emitted light in the light emission region A_{LE} may be not uniform. For this reason, in the configuration shown in the seventh example, it is preferable to form the protective layer 124 with a resin material in order to absorb a step difference and to form the protective layer 124 relatively thick, for example, about 1 μm.

In addition, as other measures for avoiding the influence of a step difference, a light shielding part (aperture) may be provided on a surface of the glass substrate 100, which is opposite to a surface on which the electroluminescent element 110 is formed, in at least a portion where the light emission region A_{LE} shown in FIG. 29 and the semiconductor island region A_{R} overlap each other. In this case, in order to cause the reflected light to be reliably incident on the channel layer 121i of the light detection element 120, it is preferable throughput the aperture be formed of a material having both a light shielding function and a reflection function, that is, a metal layer made of Al, for example. The angle of reflected light may be changed by processing a surface (side being in contact with the glass substrate 100) of the aperture.

### EIGHTH EXAMPLE

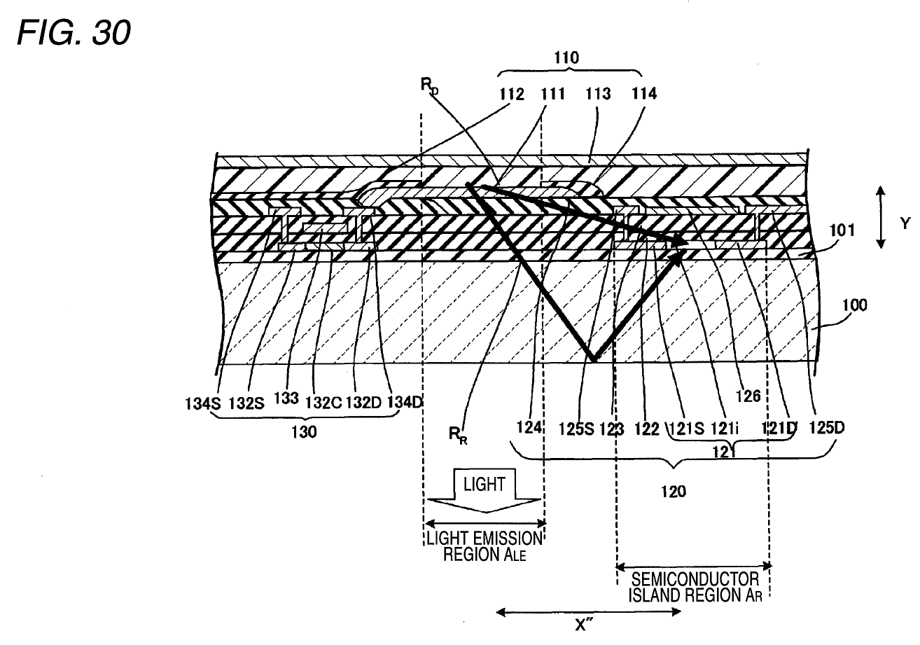

In the sixth example, the light emitting element 110 and the light detection element 120 are largely shifted from each other in the horizontal direction such that there is no overlapping region. However, in the eighth example, as shown in FIG. 30, both reflected light and direct light can be received by making the shifted amount small enough not to allow an overlapping region to occur.

That is, in the light emitting device described above, as shown in FIG. 29, the electroluminescent element 110 serving as a light source is formed at a position (position distant by X″ in the horizontal direction and Y in the vertical direction) upwardly inclined from the light detection element 120 with the control gate 126 interposed therebetween, such that light emitted from the electroluminescent element 110 serving as the light source is incident, as the direct light R_{D}, on the channel layer 121i of a thin film transistor that forms the light detection element 120 and the reflected light R_{R} reflected from an interface between the glass substrate 100 and an air layer is incident on the channel layer 121i from the lower side. The configuration of the light emitting device is the same as those in the sixth and seventh examples except that only relative positions of the light emitting element 110 and the light detection element 120 are different. The distances X′ and Y are determined from the simulation result described in the third embodiment.

In this case, since the source electrode 125S is disposed on an optical path until light emitted from the electroluminescent element 110 reaches the channel region 121i, the direct light may be blocked. Therefore, in the structure shown in the eighth example, the source electrode 125S may be divided into a plurality of electrodes (that is, in the form of a plurality of slits) in order to secure an optical path or a transparent electrode, such as ITO, may be used as the source electrode 125S.

### NINTH EXAMPLE

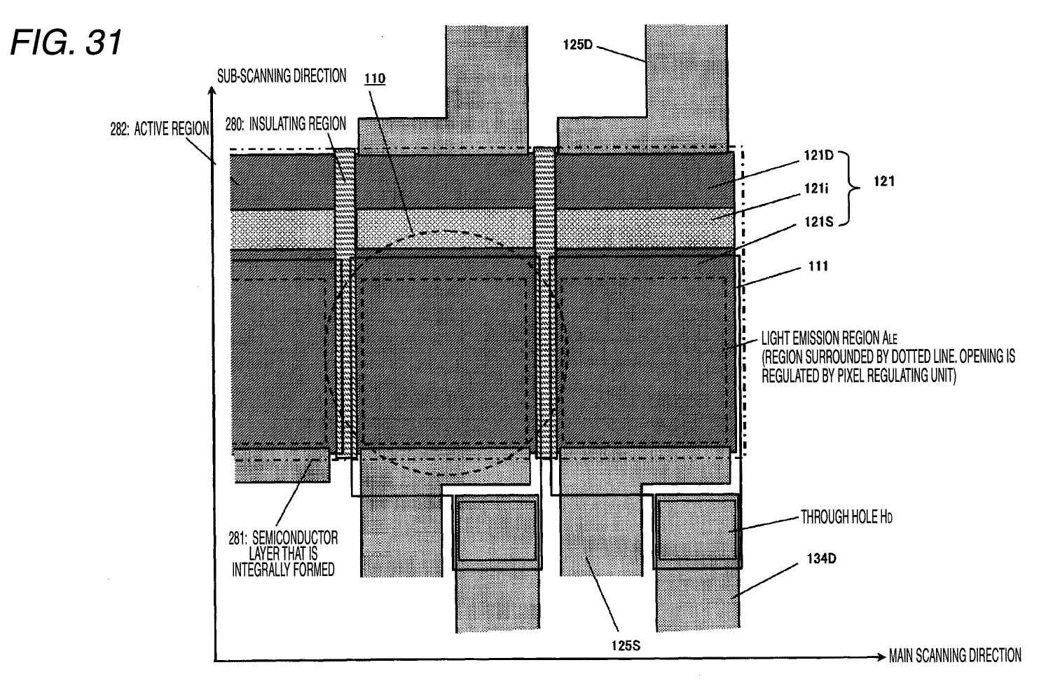

In the sixth to eighth examples described above, the light detection region of the light detection element 120 is formed using an island region made of polycrystalline silicon. However, in a ninth example, as shown in FIG. 31, a polycrystalline silicon layer (not shown) is formed on the entire element formation region surface of a glass substrate with a base coat layer (not shown) interposed therebetween, and regions excluding the source and drain regions 121S and 121D and the channel layer 121i (active region 282) of the light detection element 120 become insulated as a silicon oxide layer (insulating region 280) by injection of oxygen ions, such that unevenness of a surface is eliminated.

The other configurations are the same as that in the sixth example.

FIG. 31 is a view illustrating the configuration near the light detection element 120 of an optical head, in which the light detection element 120 is mounted, in the ninth example of the invention.

Even in the ninth example, the electroluminescent element 110 serving as a light source is formed at a position (position distant by X′″ in the horizontal direction and Y in the vertical direction; not shown) upwardly inclined from the light detection element 120 with the control gate 126 interposed therebetween, such that light emitted from the electroluminescent element 110 serving as the light source is reflected on an interface between the glass substrate 100 and an air layer and is then incident, as the reflected light RR, on the channel region 121i of the light detection element 120 from a lower side. Even in this example, the distances X′″ and Y are determined from the simulation result described in the third embodiment.

In the ninth example, a semiconductor layer that forms the light detection element 120 is integrally formed. In this configuration, the plurality of light detection elements 120 are integrally formed and defined as a semiconductor layer that is integrally formed, and the light detection elements 120 are electrically separated from each other by the insulating region 280.

That is, the light detection element 120 is formed in a semiconductor layer that is integrally formed in a strip shape on the substrate 100 (that is, the separation region 280 is formed in the semiconductor layer formed in the strip shape, and the semiconductor island region A_{R} that is surrounded by the separation region 280 and is electrically active), the light emission region A_{LE} Of the light emitting element 110 is disposed inside the light detection element 120 formed in the semiconductor layer, an electrode (anode 111) of the light emitting element 110, which is located at a lower side of the light emitting element 110, is formed to cover a part of the semiconductor layer, and the light emission region A_{LE} is formed smaller than the electrode (anode 111) located at the lower side.

In order to realize such a configuration, for example, the polycrystalline silicon (semiconductor layer 281 that is integrally formed) that is integrally formed in a strip shape may be selectively insulated by using anodic oxidation or doping of oxygen ions, such that the semiconductor island region A_{R} is element-separated into the insulating regions 280 having electrical insulation property. That is, the active region 282 divided into the insulating regions 280 insulated as described above forms the light detection element 120. In this case, since the active region 282 and the insulating region 280 around the periphery thereof are formed on the same plane, it is possible to dispose the light emission region A_{LE} on a flat surface. Thus, it is possible to realize desired formation of elements while maintaining the flatness of a surface of the light detection element 120.

Referring to FIG. 31, a state in which the active region 282 is formed by dividing the semiconductor layer 281, which is formed in the strip shape along the main scanning direction, by means of the insulating region 280 is shown. However, the semiconductor layer 281 may be largely formed also in the sub-scanning direction such that a vicinity (excluding portions corresponding to the source and drain electrodes 125S and 125D) of the active region 282 is surrounded by the insulating region 280.

A case in which the configuration is applied to, for example, the light emitting device shown in the sixth example will be described with reference to FIGS. 31 and 28. Referring to FIG. 28, the semiconductor regions that form the light detection element 120 are drawn in the island shape. However, in this explanation, the semiconductor regions are integrally formed and are electrically separated by insulation processing, such as doping of oxygen ions described above.

In this case, a transmissive substrate having an insulation property is used, and the light detection element 120 is formed by using a semiconductor element having a semiconductor layer formed on the transmissive substrate as the active region 282. At this time, the light emitting element 110 is preferably configured such that a first electrode (anode 111) formed using a transmissive conductive layer (for example, ITO) formed to cover a semiconductor layer, the light emitting layer 112 formed on the first electrode, and a second electrode (cathode 113) formed on the light emitting layer 112 are included and the light emitting layer 112 is caused to emit light by applying an electric field between the first and second electrodes.

According to the configuration described above, since unevenness due to the light detection element is not generated in the light emitting layer, it is possible to make the thickness of the light emission region of the light emitting layer uniform. As a result, since a variation in current flowing through the light emitting layer decreases, it is possible to prevent emission distribution, which is not uniform, and a life time of an optical head from becoming short.

Moreover, in the example described above, the polycrystalline silicon layer is used as a material that forms a light detection element. However, even if amorphous silicon is used, insulation separation for every element region may also be performed similarly by performing insulation while maintaining a surface smooth by means of injection of oxygen ions.

### TENTH EXAMPLE

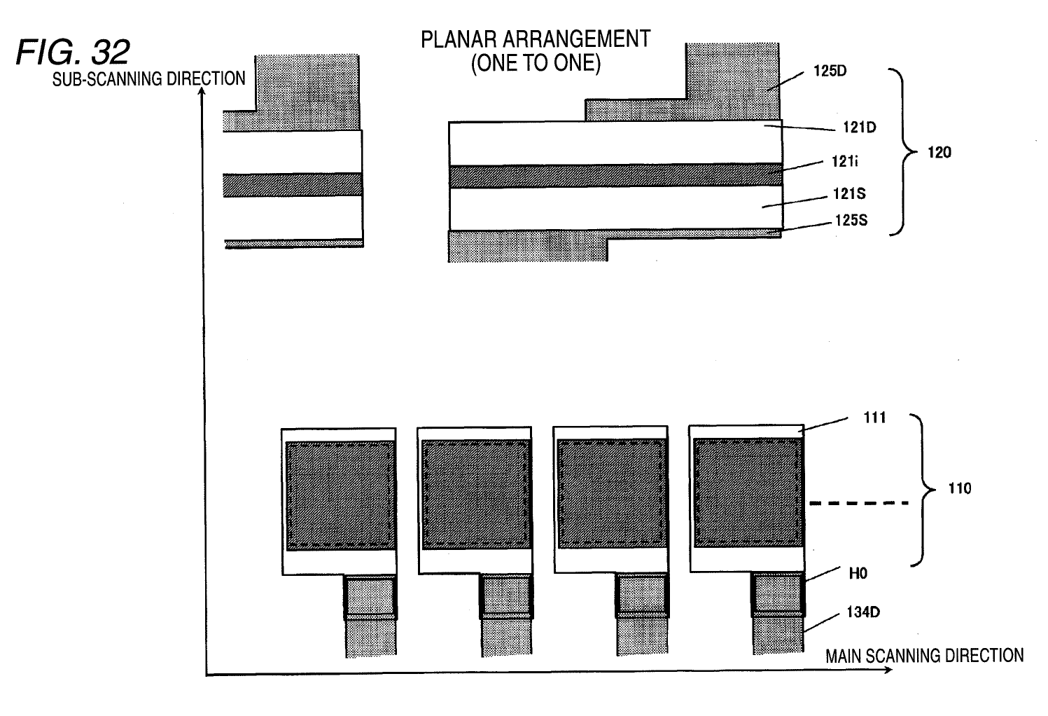

In the sixth example described above, the light emitting element 110 and the light detection element 120 are disposed to correspond in an one to one manner. However, in a tenth example, one light detection element 120 is disposed with respect to three light emitting elements 110, as shown in FIG. 32.

According to the configuration, it is possible to increase the amount of detected light and to high-sensitivity light detection.

### ELEVENTH EXAMPLE

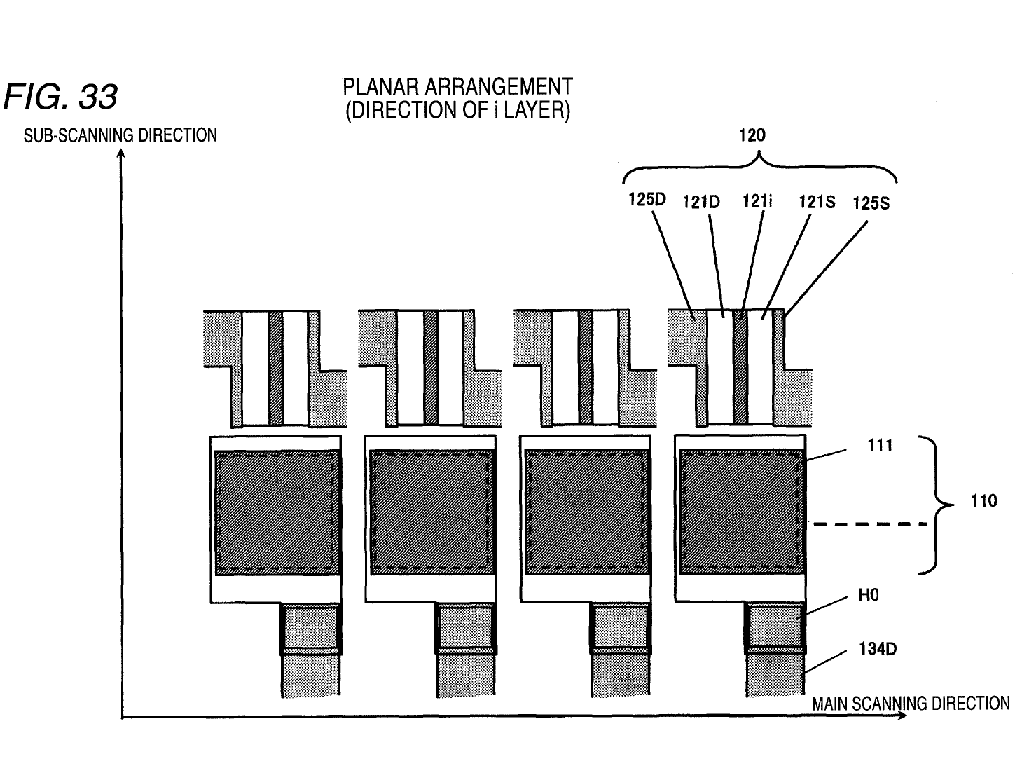

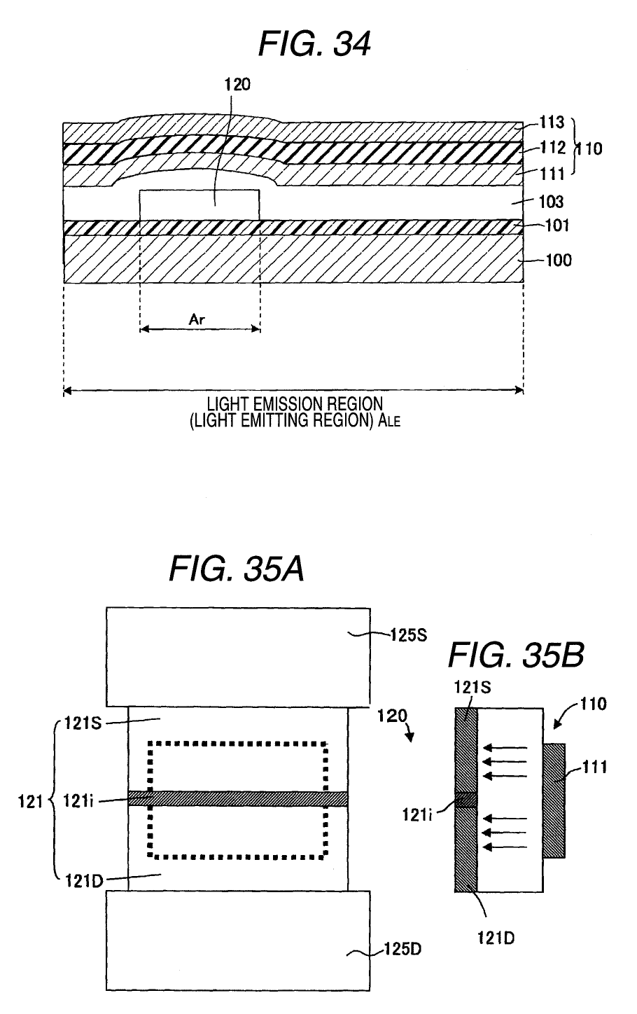

In the sixth example described above, the channel region 120i that forms the light emission region of the light detection element 120 is disposed to be parallel to the arrangement direction of light emitting elements. However, as shown in FIG. 33, an eleventh example is characterized in that the channel region 120i is disposed to be perpendicular to the arrangement direction of the light emitting elements 110. According to this configuration, it is possible to reduce crosstalk even if the absolute amount of received light slightly decreases. Since the others are the same as that in the sixth example, an explanation thereof will be omitted.

Hereinbefore, the configurations and the operations of the electroluminescent element 110 and the light detection element 120 that form the optical head have been described in detail. In the sixth to eleventh examples, a case in which light emitting elements (electroluminescent elements) are arranged in a row in the optical head has been described. However, a plurality of rows of light emitting elements may be provided to substantially increase the amount of received light.

In the following examples, the configuration or the size of each region are considered. In addition, the following examples may also be applied to the embodiments and the examples described above.

For example, in a light emitting device which has an electroluminescent element as a light source and in which a light detection element, which monitors light emitted from the electroluminescent element and generates an electrical signal used for correction of light, is disposed to overlap the electroluminescent element, an element region of the light detection element is larger than a luminous region, that is, a light emission region of the electroluminescent element and in particular, the light emission region of the electroluminescent element is formed inside the element region of the light detection element. Furthermore, by making a control gate (gate electrode) of the light detection element larger than the light emission region of the electroluminescent element and forming the light emission region of the electroluminescent element inside the element region of the light detection element, unevenness due to the light detection element is not generated in a light emitting layer. Accordingly, it is possible to make the thickness of the light emission region of the light emitting layer uniform.

As a result, since a variation in current flowing through the light emitting layer decreases, it is possible to prevent emission distribution, which is not uniform, and a life time of an optical head from becoming short. Here, an electrode of the electroluminescent element located at a lower layer side thereof is larger than a semiconductor region, and the semiconductor region is larger than the light emission region. In addition, electrodes of the light emission region, the element region, and the electroluminescent element are formed sequentially larger so as to have a margin of 1 μm or more.

Furthermore, by regulating the light emission region by means of a pixel regulating unit that is formed by interposing an insulating layer having an opening between an anode and a light emitting layer, it is possible to dispose the light emission region inside the light receiving region of the light detection element. Accordingly, since unevenness due to the light detection element is not generated in the light emitting layer, it is possible to make the thickness of the light emission region of the light emitting layer uniform. As a result, since a variation in current flowing through the light emitting layer decreases, it is possible to prevent emission distribution, which is not uniform, and a life time of an optical head from becoming short. Although the pixel regulating unit is herein formed using an insulating layer provided on at least one of an anode and a cathode so as to electrically control the light emission region, a pixel may be optically controlled by using a light shielding layer provided with an opening. In the case of forming the pixel regulating unit and electrodes of the electroluminescent element or the semiconductor layer located at a lower layer side thereof, a difference of sizes therebetween needs to be sufficiently large if positioning precision or precision after completion when forming each of those described above is taken into consideration. As a result, the light emission region may not be sufficiently large. However, by using a semiconductor layer that is integrally formed, it is possible to make the light emission region sufficiently large without taking a process of the semiconductor layer into consideration.

Furthermore, by regulating the light emission region by means of the pixel regulating unit that is formed by interposing an insulating layer having an opening between an anode and a light emitting layer, it is possible to dispose the light emission region inside the light receiving region of the light detection element. Accordingly, since unevenness due to the light detection element is not generated in the light emitting layer, it is possible to make the thickness of the light emission region of the light emitting layer uniform. As a result, since a variation in current flowing through the light emitting layer decreases, it is possible to prevent emission distribution, which is not uniform, and a life time of an optical head from becoming short. Although the pixel regulating unit is herein formed using an insulating layer provided on at least one of an anode and a cathode so as to electrically control the light emission region, a pixel may be optically controlled by using a light shielding layer provided with an opening.

Furthermore, in the invention, since a plurality of light emission regions are disposed in rows and one light detection element is disposed corresponding to one light emission region, light output from the plurality of light emission regions can be simultaneously measured independently from each other. As a result, it becomes possible to measure the amount of light in the entire light emitting device at high speed.

Furthermore, since an organic electroluminescent element is used as a light source, low electric power and high brightness can be realized. As a result, it is possible to provide a light emitting device excellent in terms of power consumption.

In addition, an inorganic electroluminescent element may also be used as a light source. The inorganic electroluminescent element is excellent in terms of stability because a light emitting layer is formed of an inorganic material and there are few defects at the time of production because screen printing is possible. In addition, since a facility, such as a clean room, is not required, high mass productivity is realized. As a result, it becomes possible to provide a light emitting device excellent in terms of a manufacturing cost.

Furthermore, by causing an electrical signal, which is suitable for correction of the amount of light, to be fed back from a light detection element to an electroluminescent element, it becomes possible to properly control the amount of light.

Furthermore, since a thin film transistor and a light detection element are formed on the same layer using a processing method, such as etching, it becomes possible to simplify a process of manufacturing the light emitting device and to reduce a cost required for manufacturing. Particularly, the process of forming a polycrystalline silicon layer on a glass substrate includes a high temperature process, but it becomes possible to obtain characteristics which are controllable very easily and are highly reliable.

In addition, sizes of an electrode of an electroluminescent element located at a lower layer side thereof, a semiconductor region, and a light emission region become smaller in this order and each of the electrode, the semiconductor region, and the light emission region has a margin of 1 μm such that the sizes are decreased by 1 μm or more. Accordingly, even if non-uniform thickness distribution, variation in position, and variation in size due to an element manufacturing process occur, it is possible to form a highly reliable light emitting device with high efficiency. Particular in a case of considering that a light emitting device is made large, variation and the like occurring due to the element manufacturing process increases. For example, if a current typical process of manufacturing a thin film transistor on a glass substrate is taken into consideration, it is possible to easily form the light emitting device by securing a margin of about 1 μm or more.

Moreover, in the case of forming a light emitting layer using a wet method, a more uniform light emitting layer can be formed on a flat surface. Particular in the case of the wet method, layers are formed according to characteristics of a material, such as wettability or viscosity of a coated light emitting layer. Accordingly, if the light emitting layer is formed on a surface having unevenness, a variation in layer thickness occurs. However, by forming the light emitting layer on a flat surface, the light emitting layer can be formed by simple processing without using a vacuum apparatus and the like.

Furthermore, an image forming apparatus excellent in terms of durability and image quality can be obtained by mounting the light emitting device of the invention which has uniform light emission distribution.

Furthermore, since the total amount of emitted light can be detected by adopting the structure in which a light detection element is disposed immediately above or immediately below an electroluminescent element, it is possible to detect the amount of light with high accuracy even when the sensitivity of the light detection element 120 is not sufficient. Accordingly, by controlling the amount of emitted light of the electroluminescent element in correspondence with the detect amount of light, it is possible to make the amount of light stable.

In addition, a light detection element may be disposed to be shifted in the inclined direction of an electroluminescent element without being disposed immediately above the electroluminescent element so as to overlap the electroluminescent element. In the case of a light emitting device that causes the electroluminescent element to emit light with high brightness, if total light is illuminated onto a light detection element, the light detection element may deteriorate due to exposure of the light. However, it is possible to increase the life time of the light detection element by detecting diffused light.

Furthermore, as for the structures of the electroluminescent element 110 and the light detection element 120 described in the first to eleventh examples, it is also possible to apply to a display device, such as a display, that obtained by displaying the electroluminescent elements 110 and the light detection elements 120 in a two-dimensional manner.

In addition, although the control gate 126 may be used as a light shielding unit that blocks direct light emitted from the electroluminescent element from being incident on the light detection element 120, a thin layer having a light shielding property may also be provided at a predetermined position on an optical path separately from the control gate 126.

The same is true for a light shielding unit that blocks external reflected light from being incident on the light detection element 120 and a light shielding unit that blocks reflected light from the electroluminescent element 110 from being incident on the light detection element 120. Thus, it is possible to easily improve the light shielding property by disposing a thin layer having a light shielding property at the predetermined position on the optical path.

In addition, an optical head may be formed using the light emitting device described above, or it is possible to provide an image forming apparatus using the optical head as an exposure unit for image formation.

The light emitting device of the invention may be applied to a display device, a copying machine, a printer, a multi-function printer, a facsimile, and the like.

This application is based upon and claims the benefit of priority of Japanese Patent Application No 2006-247265 filed on Sep. 12, 2006 Japanese Patent Application No 2006-340372 filed on Dec. 18, 2006 the contents of which are incorporated herein by reference in its entirety.

What is claimed is:

1. A light emitting device comprising:
an electroluminescent element; and
a light detection element that detects light output from the electroluminescent element,
wherein the electroluminescent element and the light detection element are disposed to be laminated, and
the light detection element includes:
a photoelectric conversion unit; and
a control gate that is formed so as to be electrically insulated from an electrode of the electroluminescent element and controls an electric potential of the photoelectric conversion unit.

2. The light emitting device according to claim 1, wherein the light detection element is formed using a transistor.

3. The light emitting device according to claim 1, wherein the light detection element is formed using a diode.

4. The light emitting device according to claim 2, wherein the light detection element is formed using a thin film transistor, and
the thin film transistor has a control gate that is formed so as to be electrically insulated and separated from an electrode of the electroluminescent element.

5. The light emitting device according to claim 1, wherein the control gate is provided above or below the photoelectric conversion unit so as to cover at least a part of the photoelectric conversion unit at least.

6. The light emitting device according to claim 5, wherein the electroluminescent element is laminated on the light detection element formed on a substrate, and
an element region of a thin film transistor that forms the light detection element is formed larger than a light emission region of the electroluminescent element so as to cover the light emission region.

7. The light emitting device according to claim 6, wherein the element region is a polycrystalline silicon island region.

8. The light emitting device according to claim 6, wherein the element region is an amorphous silicon island region.

9. The light emitting device according to claim 1, wherein the electroluminescent element is laminated on the light detection element formed on a substrate, and
an outer edge of an element region of the light detection element is formed to become an outer side of a light emission region of the electroluminescent element.

10. The light emitting device according to claim 9,
wherein the substrate is a transmissive glass substrate,
the light detection element is a thin film transistor having a semiconductor layer formed on the transmissive glass substrate as an active region,
the electroluminescent element includes a first electrode formed by using a transmissive conductive layer formed to cover the semiconductor layer, a light emitting layer formed on the first electrode, and a second electrode formed on the light emitting layer, and
the light emitting layer emits light by applying an electric field between the first and second electrodes.

11. The light emitting device according to claim 10,
wherein the thin film transistor has the control gate disposed on the semiconductor layer.

12. The light emitting device according to claim 11,
wherein the control gate is formed of a transmissive material.

13. The light emitting device according to claim 10,
wherein the thin film transistor has the control gate disposed below the semiconductor layer.

14. The light emitting device according to claim 13,
wherein the control gate is formed of a transmissive material.

15. The light emitting device according to claim 13,
wherein the control gate is formed of a reflective material.

16. The light emitting device according to claim 13,
wherein the control gate is integrally formed over almost the entire surface of the glass substrate.

17. The light emitting device according to claim 9,
wherein the control gate is a metal electrode disposed in a line shape, and
both ends of the control gate in the longitudinal direction thereof are formed outside a light emission region of the electroluminescent element.

18. The light emitting device according to claim 9,
wherein the substrate has a reflective surface, and
light is emitted toward an upper layer side of the substrate.

19. The light emitting device according to claim 9,
wherein the substrate is a transmissive substrate, and
light is emitted toward the substrate side.

20. The light emitting device according to claim 1,
wherein a part or all of the light detection element is disposed outside a light emission region of the electroluminescent element such that the part or all of the light detection element is laminated on the electroluminescent element excluding the light emission region.
